(19) United States
(12) Patent Application Publication
(10) Pub. No.: US 2013/0077383 A1
(43) Pub. Date: Mar. 28, 2013

(54) Writing Circuit for a Resistive Memory Cell Arrangement and a Memory Cell Arrangement

(71) Applicant: Agency for Science, Technology and Research, Singapore (SG)

(72) Inventors: Kejie HUANG, Singapore (SG); Rong ZHAO, Singapore (SG)

(73) Assignee: AGENCY FOR SCIENCE, TECHNOLOGY AND RESEARCH, Singapore (SG)

(21) Appl. No.: 13/623,451

(22) Filed: Sep. 20, 2012

(30) Foreign Application Priority Data
Sep. 23, 2011 (SG) 201106907-7

(51) Int. Cl. G11C 7/00

(52) U.S. Cl. 365/148

(57) ABSTRACT

A writing circuit for a resistive memory cell arrangement is provided, the resistive memory cell arrangement including a plurality of resistive memory cells. The writing circuit includes a controlled voltage source including a plurality of pass transistors, wherein each pass transistor includes a first source/drain terminal, a second source/drain terminal and a gate terminal, and wherein the first source/drain terminal is configured to be electrically coupled to a power supply line and the second source/drain terminal is configured to be electrically coupled to a bit line associated with a resistive memory cell of the plurality of resistive memory cells, and a plurality of switches, wherein each switch is configured to control the gate terminal of the pass transistor, wherein the controlled voltage source is configured to supply a voltage to the resistive memory cell for a write operation. Further embodiments provide a resistive memory cell arrangement.

This application claims the benefit of priority of Singapore patent application No. 201106907-7, filed Sep. 23, 2011, the contents of which are incorporated herein by reference for all purposes.

### FIELD OF THE INVENTIONS

Various embodiments relate to a writing circuit for a resistive memory cell arrangement and a memory cell arrangement.

### BACKGROUND OF THE INVENTIONS

Phase change memory or phase-change random access memory (PCRAM) has two states: amorphous (high resistance) and crystalline (low resistance). At either of the amorphous state or the crystalline state, the resistance of the PCRAM cells will change with the voltage that is provided on the memory cells. During set (change from the amorphous state to the crystalline state) and reset (change from the crystalline state to the amorphous state), the resistance/resistivity of the PCRAM cell changes as the resistance/resistivity of the memory cell changes.

When using current driven writing or voltage driven writing, the voltage on the PCRAM cells are uncertain. For the current driven writing approach, the voltage is uncertain as the parameter (I×R) is changed, where V=I×R, I is current and R is resistance. For the voltage driven writing approach, the voltage is uncertain because the relationship between the column selecting switch resistance and the PCRAM cell resistance is unknown and the ratio of these resistances changes. In addition, the ratio of the resistance of the column selecting switch and the resistance of the row selecting transistor will not remain the same during writing.

FIG. 1A shows a PCRAM writing circuit 100 with reference current of prior art, for current driven writing employing a reference current based writing scheme. The writing circuit 100 includes a transistor 102 having a first source/drain terminal (S/D₁) coupled to a power supply line, a second source/drain terminal (S/D₂) coupled to a current source 104 and then to ground, and a gate terminal (G) that is coupled to the respective gate terminals of a plurality of transistors, e.g. 106a, 106b. The second source/drain terminal (S/D₂) and the gate terminal (G) of the transistor 102 are coupled to each other. The current source 104 provides either a SET current (Iₛₑₜ) or a RESET current (Iᵣₑₛₑₜ), as a reference current (I_{ref}).

The first source/drain terminal (S/D₁) of each of the plurality of transistors 106a, 106b is coupled to a power supply line, and the second source/drain terminal (S/D₂) of each of the plurality of transistors 106a, 106b is coupled to a column selecting switch, e.g. 108a, 108b, which in turn is coupled to a PCRAM cell, e.g. 110a, 110b, and a first source/drain terminal (S/D₁) of a row selecting transistor, e.g. 112a, 112b. The second source/drain terminal (S/D₂) of the respective row selecting transistor 112a, 112b is coupled to ground while the gate terminal (G) of the respective row selecting transistor 112a, 112b is coupled to a word line 113.

Each column selecting switch 108a, 108b has a resistance R_{col}. Each PCRAM cell 110a, 110b has a resistance R_{pcram}. Each row selecting transistor 112a, 112b has a resistance R_{row}.

The transistor 102 forms a respective current mirror with each of the transistors 106a, 106b and as such, the same current I_{ref} flows through each of the columns, e.g. 114a, 114b. The voltage, V_{pcram}/across each PCRAM cell 110a, 110b is (I_{ref}×R_{pcram}).

In the writing circuit 100 employing the reference current based writing scheme, while I_{ref} is constant, R_{pcram} is variable as the PCRAM cells 110a, 110b change with the write voltage and have a resistance distribution, thereby changing V_{pcram} (=I_{ref}×R_{pcram}).

FIG. 1B shows a PCRAM writing circuit 130 with reference voltage of prior art, for voltage driven writing employing a reference voltage based writing scheme. The writing circuit 130 includes a first switch 132 and a second switch 134, which when closed may supply a SET voltage (Vₛₑₜ) and a RESET voltage (Vᵣₑₛₑₜ) respectively, as a reference voltage (V_{ref}) to each of a plurality of column selecting switches, e.g. 136a, 136b, which in turn is respectively coupled to a PCRAM cell, e.g. 138a, 138b, and a first source/drain terminal (S/D₁) of a row selecting transistor, e.g. 140a, 140b. The second source/drain terminal (S/D₂) of the respective row selecting transistor 140a, 140b is coupled to ground while the gate terminal (G) of the respective row selecting transistor 140a, 140b is coupled to a word line 141.

Each column selecting switch 136a, 136b has a resistance R_{col}. Each PCRAM cell 138a, 138b has a resistance R_{pcram}. Each row selecting transistor 140a, 140b has a resistance R_{row}. As the column selecting switches 136a, 136b, the PCRAM cells 138a, 138b and the transistors 140a, 140b are coupled in series in each of the columns, e.g. 142a, 142b, the total resistance in each column 142a, 142b is (R_{col}+R_{pcram}+R_{row}) and therefore, the current flowing through each column 142a, 142b and the current, I_{pcram}, flowing through each PCRAM cell 138a, 138b is (V_{ref}/(R_{col}+R_{pcram}+R_{row})). The voltage, V_{pcram}/across each PCRAM cell 138a, 138b is therefore (I_{pcram}×R_{pcram}).

In the writing circuit 130 employing the reference voltage based writing scheme, R_{pcram} is variable as the PCRAM cells 138a, 138b change with the write voltage and have a resistance distribution, and as a result, the ratio of the resistance, R_{pcram}/of the PCRAM cells 138a, 138b, and the total resistance in the column, (R_{col}+R_{pcram}+R_{row}), does not remain the same during writing, thereby changing the current, I_{pcram}, and the voltage, V_{pcram}, across each PCRAM cell 138a, 138b.

The RESET voltage may be from 1.5 V to 2 V, and during transition, the resistance of the PCRAM becomes very small and the RESET current becomes very large (between ˜100 μA and 2 mA). In such situations, as the column selecting switches are not fully turned on, the resistances of these switches cannot be neglected. For example, if the resistance of the switch is 11 kΩ, the voltage drop across the switch is 0.1 V to 2 V, and so at the worst case, the power supply needs to be more than 4 V. The large resistances of the switches not only increase the power supply for writing, but also increase the power consumption (I_{w}×I_{w}×Rₛ) where I_{w} is the writing current and Rₛ is the resistance of the switch. In order to reduce the switch resistance, one option is to increase the size of the switch, but this will increase the size of the chip, the address loading capacitance and the bit line loading capacitance accordingly, as a result, the dynamic power consumption is increased.

In addition, the time constant RC (R is resistance and C is capacitance) of the PCRAM cell will be very large after it has been RESET, and the large RC will affect the falling time of the RESET signal, which may even SET the PCRAM cell from the amorphous state to the crystalline state.

### SUMMARY

According to an embodiment, a writing circuit for a resistive memory cell arrangement is provided, the resistive memory cell arrangement including a plurality of resistive memory cells. The writing circuit may include a controlled voltage source including a plurality of pass transistors, wherein each pass transistor includes a first source/drain terminal, a second source/drain terminal and a gate terminal, and wherein the first source/drain terminal is configured to be electrically coupled to a power supply line and the second source/drain terminal is configured to be electrically coupled to a bit line associated with a resistive memory cell of the plurality of resistive memory cells, and a plurality of switches, wherein each switch is configured to control the gate terminal of the pass transistor, wherein the controlled voltage source is configured to supply a voltage to the resistive memory cell for a write operation.

According to an embodiment, a memory cell arrangement is provided. The memory cell arrangement may include a plurality of resistive memory cells, a writing circuit for the plurality of resistive memory cells, the writing circuit including a controlled voltage source including a plurality of pass transistors, wherein each pass transistor includes a first source/drain terminal, a second source/drain terminal and a gate terminal, and wherein the first source/drain terminal is configured to be electrically coupled to a power supply line and the second source/drain terminal is configured to be electrically coupled to a bit line associated with a resistive memory cell of the plurality of resistive memory cells, and a plurality of switches, wherein each switch is configured to control the gate terminal of the pass transistor, wherein the controlled voltage source is configured to supply a voltage to the resistive memory cell for a write operation.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1A shows a PCRAM writing circuit with reference current of prior art.

FIG. 1B shows a PCRAM writing circuit with reference voltage of prior art.

FIG. 2A shows a schematic block diagram of a writing circuit, according to various embodiments, for a resistive memory cell arrangement.

FIG. 2B shows a schematic block diagram of a writing circuit, according to various embodiments, for a resistive memory cell arrangement.

FIG. 2C shows a schematic block diagram of a writing circuit, according to various embodiments, for a resistive memory cell arrangement.

FIG. 2D shows a schematic block diagram of a writing circuit, according to various embodiments, for a resistive memory cell arrangement.

FIG. 2E shows a schematic block diagram of a memory cell arrangement, according to various embodiments.

FIG. 2F shows a schematic block diagram of a memory cell arrangement, according to various embodiments.

FIG. 3A shows a schematic diagram of writing voltages to SET/RESET the resistive memory cells, according to various embodiments.

FIG. 3B shows a schematic diagram of writing voltages to SET/RESET the resistive memory cells, according to various embodiments.

FIG. 4 shows a schematic of a writing circuit, according to various embodiments, for a resistive memory cell arrangement.

FIG. 5 shows a schematic of a writing circuit, according to various embodiments, for a resistive memory cell arrangement.

FIG. 6A shows a schematic of a writing circuit, according to various embodiments, for a resistive memory cell arrangement.

FIG. 6B shows a schematic of a writing circuit, according to various embodiments, for a resistive memory cell arrangement.

FIG. 6C shows a schematic of a simplified representation of the writing circuit of the embodiments of FIGS. 6A and 6B.

FIG. 6D shows a schematic of a writing circuit, according to various embodiments, for a resistive memory cell arrangement.

FIG. 6E shows a schematic of a simplified representation of the writing circuit of the embodiment of FIG. 6D.

FIG. 7A shows a schematic of a discharge circuit, according to various embodiments.

FIG. 7B shows a schematic of a discharge circuit, according to various embodiments.

FIG. 8A shows simulation results of waveforms for a writing circuit of various embodiments with discharge circuits.

FIG. 8B shows simulation results of waveforms for a writing circuit of various embodiments without discharge circuits.

### DETAILED DESCRIPTION OF THE INVENTIONS

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

Embodiments described in the context of one of the devices or circuits are analogously valid for the other devices or circuits.

Features that are described in the context of an embodiment may correspondingly be applicable to the same or similar features in the other embodiments. Features that are described in the context of an embodiment may correspondingly be applicable to the other embodiments, even if not explicitly described in these other embodiments. Furthermore, additions and/or combinations and/or alternatives as described for a feature in the context of an embodiment may correspondingly be applicable to the same or similar feature in the other embodiments.

In the context of various embodiments, the phrase “at least substantially” may include “exactly” and a variance of +/−5% thereof. As an example and not limitations, “A is at least substantially same as B” may encompass embodiments where A is exactly the same as B, or where A may be within a variance of +/−5%, for example of a value, of B, or vice versa.

In the context of various embodiments, the term “about” or “approximately” as applied to a numeric value encompasses the exact value and a variance of +/−5% of the value.

As used herein, the term “and/or” includes any and all combinations of one or more of the associated listed items.

Various embodiments relate to memory devices, for example write circuits of/for memory devices.

Various embodiments may provide writing circuits for a memory cell arrangement. The memory cell arrangement may include a plurality of memory cells. The plurality of memory cells may be resistive memory cells, thereby providing a resistive memory cell arrangement. The writing circuits may be voltage regulated writing circuits.

Various embodiments may provide a memory cell arrangement including a writing circuit and a plurality of memory cells. The plurality of memory cells may be resistive memory cells, thereby providing a resistive memory cell arrangement.

In various embodiments, the memory cell or resistive memory cell may be a phase change memory cell, the memory cell arrangement may be a phase change memory cell arrangement and the writing circuits may be phase change memory writing circuits (PCRAM writing circuits), e.g. voltage regulated phase change memory writing circuits.

Various embodiments may provide a non-volatile memory cell arrangement including a writing circuit and a plurality of non-volatile memory cells, for example resistive storage based memory cells, such as phase change random access memory (PCRAM) cells.

In various embodiments, the time constant RC (R is resistance and C is capacitance) of the resistive memory cell (e.g. PCRAM cell) may be large after it has been RESET (change of the cell from the crystalline state to the amorphous state), and the large RC may affect the falling time of the RESET signal, which may SET the PCRAM cell from the amorphous state to the crystalline state. In various embodiments, a discharge circuit may be added to the writing circuits to pull the “RESET” signal to ground quickly or immediately, so as to prevent the resistive memory cell from being changed to “SET” after the “RESET” process or operation.

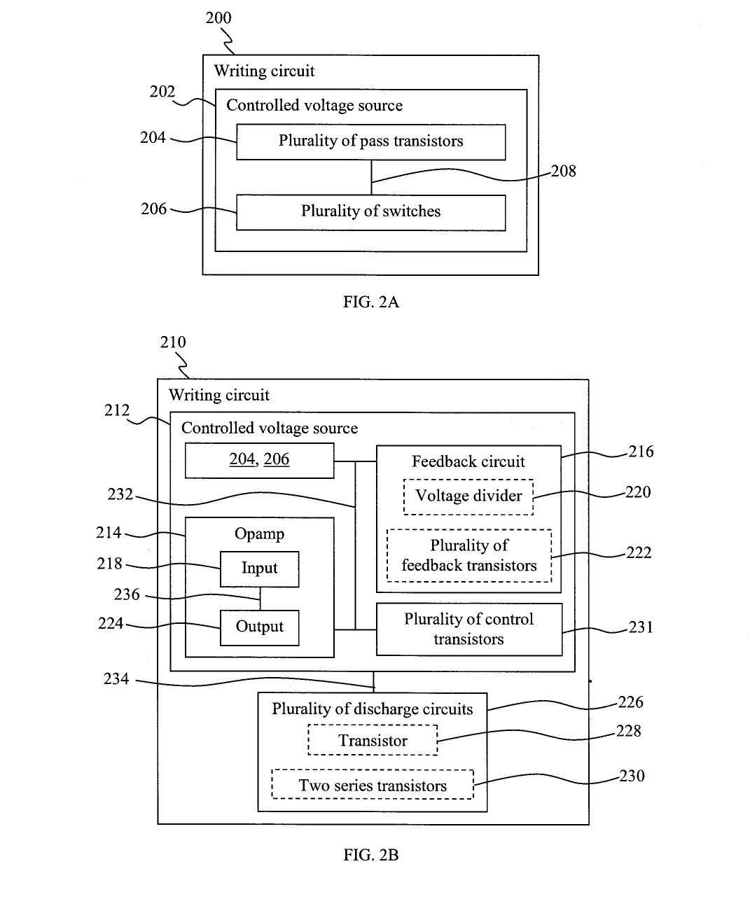

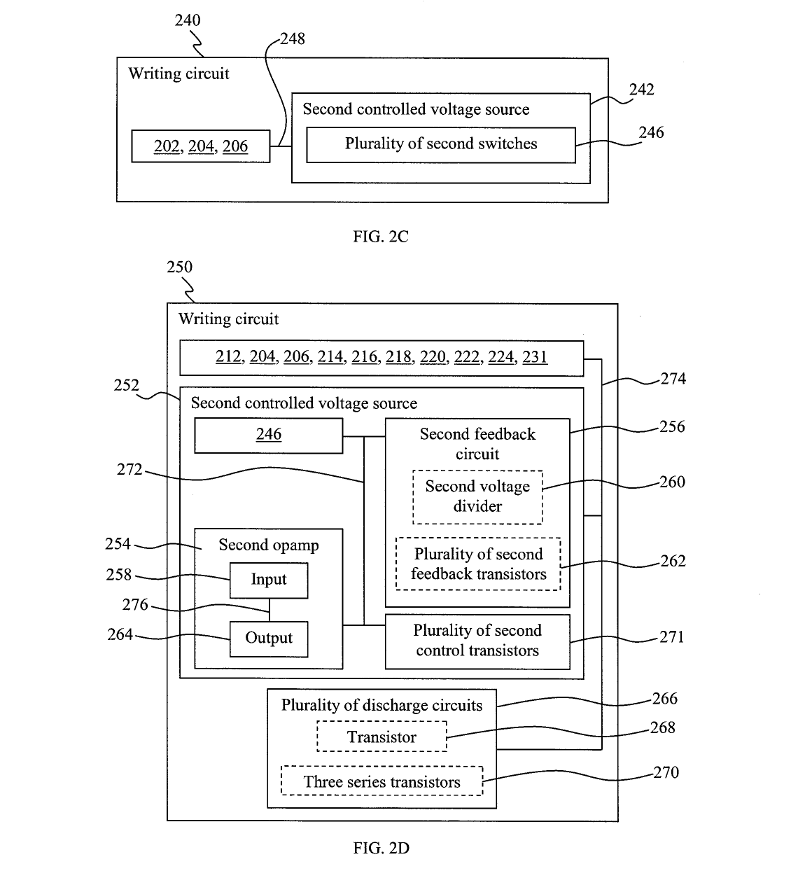

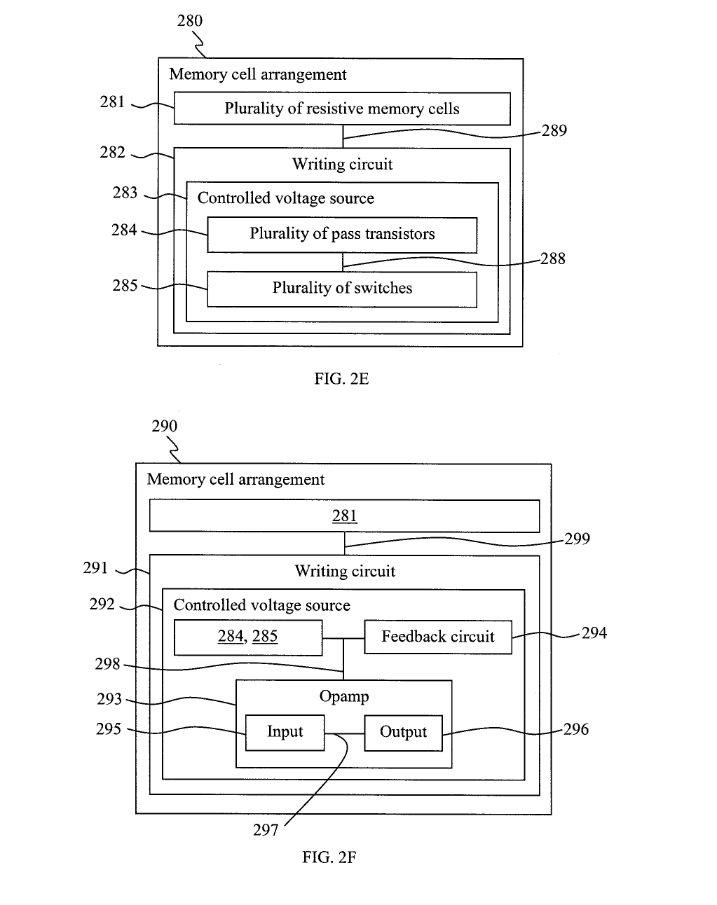

FIG. 2A shows a schematic block diagram of a writing circuit 200, according to various embodiments, for a resistive memory cell arrangement including a plurality of resistive memory cells. The writing circuit 200 includes a controlled voltage source 202. The controlled voltage source 202 includes a plurality of pass transistors (or biasing transistors) 204, wherein each pass transistor 204 includes a first source/drain terminal, a second source/drain terminal and a gate terminal, and wherein the first source/drain terminal is configured to be electrically coupled to a power supply line and the second source/drain terminal is configured to be electrically coupled to a bit line associated with a resistive memory cell of the plurality of resistive memory cells, and a plurality of switches (e.g. column enabling/disabling switches) 206, wherein each switch 206 is configured to control the gate terminal of the pass transistor 204. The controlled voltage source 202 is configured to supply a voltage to the resistive memory cell for a write operation.

In other words, the controlled voltage source 202 includes a plurality of pass transistors 204 and a plurality of switches 206, where a pass transistor 204 and a switch 206 are provided per one bit line. Therefore, different pass transistors 204 and different switches 206 are provided for different bit lines.

In various embodiments, each switch 206 may be controllable by a respective column signal (e.g. ColAᵢ) associated with the respective resistive memory cell.

In FIG. 2A, the line represented as 208 is illustrated to show the relationship between the plurality of pass transistors 204 and the plurality of switches 206, which may include electrical coupling and/or mechanical coupling.

In the context of various embodiments, the “write operation” may refer to any one of a SET operation which writes a logic state ‘1’ to a resistive memory cell or a RESET operation which writes a logic state ‘0’ to a resistive memory cell. In other words, the “write operation” may mean an operation where a data bit (e.g. logic ‘1’ or logic ‘0’) may be written and/or stored in the resistive memory cell.

FIG. 2B shows a schematic block diagram of a writing circuit 210, according to various embodiments, for a resistive memory cell arrangement including a plurality of resistive memory cells. The writing circuit 210 includes a controlled voltage source 212. The controlled voltage source 212 includes a plurality of pass transistors 204 and a plurality of switches 206, which may be similar to the embodiments as described in the context of FIG. 2A.

In various embodiments, each switch 206 may be controllable by a respective first column signal (e.g. ColAᵢ) associated with the respective resistive memory cell.

The controlled voltage source 212 may further include an opamp 214 for regulating the voltage during the write operation.

The controlled voltage source 212 may further include a feedback circuit 216 configured to be electrically coupled to an input 218 of the opamp 214 and the plurality of resistive memory cells.

In various embodiments, the feedback circuit 216 includes a voltage divider 220. In various embodiments, the voltage divider 220 may be an adjustable voltage divider, e.g. a potentiometer. In other embodiments, the voltage divider 220 may include two resistors coupled in series, and connected between the plurality of resistive memory cells (e.g. connected or electrically coupled to a common node connected or electrically coupled to the plurality of resistive memory cells) and a ground or a voltage terminal, with the input 218 of the opamp 214 connected or electrically coupled to a node located between the two series resistors. In various embodiments, the voltage divider 220 may include any number of resistors coupled in series, with the input 218 of the opamp 214 connected or electrically coupled to a node located between any two adjacent series resistors.

In various embodiments, the feedback circuit 216 includes a plurality of feedback transistors 222, wherein each feedback transistor 222 includes a first feedback source/drain terminal, a second feedback source/drain terminal and a feedback gate terminal, and wherein the first feedback source/drain terminal is configured to be electrically coupled to the bit line associated with the resistive memory cell and the second feedback source/drain terminal is configured to be electrically coupled to the input 218 of the opamp 214. In other words, a feedback transistor 222 is provided per one bit line. Therefore, different feedback transistors 222 are provided for different bit lines. In various embodiments, each feedback transistor 222 may be controllable by a respective column signal (e.g. ColAᵢ) associated with the respective resistive memory cell, e.g. the column signal ColAᵢ may control the gate terminal of the respective feedback transistor 222.

In various embodiments, each pass transistor 204 may be configured to be directly connected to the bit line associated with the resistive memory cell.

In various embodiments, each switch 206 of the plurality of switches 206 may be electrically coupled to an output 224 of the opamp 214 for controlling the gate terminal of the pass transistor 204 based on a signal from the output 224 of the opamp 214.

In various embodiments, the controlled voltage source 212 may further include a plurality of control transistors (e.g. column enabling/disabling transistors) 231, wherein each control transistor 231 is configured to be electrically coupled between the gate terminal of the pass transistor 204 and the power supply line. For example, each control transistor 231 includes a first control source/drain terminal, a second control source/drain terminal and a control gate terminal, and wherein the first control source/drain terminal is configured to be electrically coupled to the gate terminal of the pass transistor 204 and the second control source/drain terminal is configured to be electrically coupled to the power supply line. In various embodiments, each control transistor 231 may be controllable by a respective column signal (e.g. ColAᵢ) associated with the respective resistive memory cell, e.g. the column signal ColAᵢ may control the gate terminal of the respective control transistor 231.

The opamp 214 may have an inverting input (V₋) and a non-inverting input (V₊), wherein the input 218 may be the non-inverting input (V₊).

In various embodiments, the writing circuit 210 may further include a plurality of discharge circuits 226, wherein each discharge circuit 226 of the plurality of discharge circuits 226 may be configured to be electrically coupled between the bit line associated with the resistive memory cell and a ground terminal. In other words, a discharge circuit 226 is provided per one bit line. Therefore, different discharge circuits 226 are provided for different bit lines.

In various embodiments, each discharge circuit 226 includes a transistor 228 controllable to discharge the bit line after the write operation. The transistor 228 may be controllable by another respective column signal (e.g. ColCᵢ) associated with the respective resistive memory cell. The respective column signal ColCᵢ may be a function of the respective column signal ColAᵢ associated with the same respective resistive memory cell, for example the column signal ColCᵢ is only high and the transistor 228 enabled for discharging the bit line, immediately after the negative edge or falling edge of ColAᵢ and becomes low again after a short time period.

In further embodiments, each discharge circuit 226 includes a transistor 228 controllable to discharge the bit line after the write operation and a read operation. In other words, the transistor 228 may be controllable to discharge the bit line after both the write operation and the read operation have been performed or completed. The transistor 228 may be controllable by another respective column signal (e.g. ColCᵢ) associated with the respective resistive memory cell. The respective column signal ColCᵢ may be a function of a combination of the respective column signal ColAᵢ and a respective read enable signal (e.g. RE) associated with the same respective resistive memory cell, for example the column signal ColCᵢ is high and the transistor 228 is enabled for discharging the bit line when the column signal ColAᵢ and the read enable signal RE are low (e.g. ColCᵢ results from an inverse ColAᵢ AND an inverse RE;

ColCᵢ=!ColAᵢ*!RE, where “!” represents an inverse function and “*” represents an AND function).

In other embodiments, each discharge circuit 226 includes two transistors 230 coupled in series to each other, wherein the two transistors 230 are cooperatively controllable to discharge the bit line after the write operation and after a read operation. In other words, the two series transistors 230 may allow the bit line to be discharged after both the write operation and the read operation have been performed or completed. This may ensure that the no write operation and/or read operation is performed during discharging or that discharging operation is not enabled during write operation and/or read operation.

One of the two series transistors 230 may be controllable by the respective column signal ColAᵢ while the other of the two series transistors 230 may be controllable by a respective read enable signal (e.g. RE) associated with the same respective resistive memory cell. Therefore, the bit line may be discharged when both of the two series transistors 230 are enabled, for example the discharge operation is a function of an inverse ColAᵢ AND an inverse RE (e.g. !ColAᵢ*!RE, where “!” represents an inverse function and “*” represents an AND function).

In various embodiments, the controlled voltage source 212 may be free of any switch along an electrical path defined between the second source/drain terminal of the pass transistor 204 and the bit line.

In FIG. 2B, the line represented as 232 is illustrated to show the relationship among the plurality of pass transistors 204, the plurality of switches 206, the opamp 214, the feedback circuit 216 and the plurality of control transistors 231, which may include electrical coupling and/or mechanical coupling, the line represented as 234 is illustrated to show the relationship between the controlled voltage source 212 and the plurality of discharge circuits 226, which may include electrical coupling and/or mechanical coupling, while the line represented as 236 is illustrated to show the relationship between the input 218 and the output 224 of the opamp 214, which may include electrical coupling and/or mechanical coupling.

FIG. 2C shows a schematic block diagram of a writing circuit 240, according to various embodiments, for a resistive memory cell arrangement including a plurality of resistive memory cells. The writing circuit 240 includes a controlled voltage source 202, including a plurality of pass transistors 204 and a plurality of switches 206, which may be similar to the embodiments as described in the context of FIG. 2A.

The writing circuit 240 may further include a second controlled voltage source 242 including a plurality of second switches (e.g. second column enabling/disabling switches) 246, wherein each second switch 246 is configured to control the gate terminal of the pass transistor 204, wherein the second controlled voltage source 242 is configured to supply a second voltage to the resistive memory cell for a second write operation.

In other words, the second controlled voltage source 242 includes a plurality of second switches 246, where a second switch 246 is provided per one bit line. Therefore, different second switches 246 are provided for different bit lines.

In various embodiments, each second switch 246 may be controllable by a respective other column signal (e.g. ColBᵢ) associated with the respective resistive memory cell.

In FIG. 2C, the line represented as 248 is illustrated to show the relationship between the controlled voltage source 202 and the second controlled voltage source 242, which may include electrical coupling and/or mechanical coupling.

In the context of various embodiments, the “second write operation” may refer to any one of a SET operation which writes a logic state ‘1’ to a resistive memory cell or a RESET operation which writes a logic state ‘0’ to a resistive memory cell. However, the “write operation” due to the controlled voltage source 202 and the “second write operation” due to the second controlled voltage source 242 are different operations, in that in embodiments where the controlled voltage source 202 is configured for the SET operation, the second controlled voltage source 242 is configured for the RESET operation. In further embodiments, the controlled voltage source 202 may be configured for the RESET operation while the second controlled voltage source 242 may be configured for the SET operation.

In other words, the write operation and the second write operation respectively result in a first logic state and a second logic state of the respective resistive memory cell, the first logic state and the second logic being different logic states, e.g. the first logic state may be the logic state ‘0’ and the second logic state may be the logic state ‘1’, or vice versa. Therefore, the “second write operation” may mean an operation where a data bit (e.g. logic ‘1’ or logic ‘0’) may be written and/or stored in the resistive memory cell, and that the data bit written and/or stored for the “second write operation” is different from the data bit written and/or stored for the “write operation”.

FIG. 2D shows a schematic block diagram of a writing circuit 250, according to various embodiments, for a resistive memory cell arrangement including a plurality of resistive memory cells. The writing circuit 250 includes a controlled voltage source 212 including a plurality of pass transistors 204, a plurality of switches 206 and an opamp 214, which may be similar to the embodiments as described in the context of FIGS. 2A and 2B. The writing circuit 250 further includes a second controlled voltage source 252. The second controlled voltage source 252 includes a plurality of second switches 246, which may be similar to the embodiments as described in the context of FIG. 2C. The second controlled voltage source 252 may further include a second opamp 254 for regulating the second voltage during the second write operation.

In various embodiments of the writing circuit 250, the controlled voltage source 212 may further include a feedback circuit 216, which may be similar to the embodiments as described in the context of FIG. 2B, and the second controlled voltage source 252 may further include a second feedback circuit 256 configured to be electrically coupled to an input 258 of the second opamp 254 and the plurality of resistive memory cells.

In various embodiments, the second feedback circuit 256 includes a second voltage divider 260. In various embodiments, the second voltage divider 260 may be an adjustable voltage divider, e.g. a potentiometer. In other embodiments, the second voltage divider 260 may include two resistors coupled in series, and connected between the plurality of resistive memory cells (e.g. connected or electrically coupled to a common node connected or electrically coupled to the plurality of resistive memory cells) and a ground or a voltage terminal, with the input 258 of the second opamp 254 connected or electrically coupled to a node located between the two series resistors. In various embodiments, the second voltage divider 260 may include any number of resistors coupled in series, with the input 258 of the second opamp 254 connected or electrically coupled to a node located between any two adjacent series resistors.

In various embodiments, the second feedback circuit 256 includes a plurality of second feedback transistors 262, wherein each second feedback transistor 262 includes a first feedback source/drain terminal, a second feedback source/drain terminal and a feedback gate terminal, and wherein the first feedback source/drain terminal is configured to be electrically coupled to the bit line associated with the resistive memory cell and the second feedback source/drain terminal is configured to be electrically coupled to the input 258 of the second opamp 254.

In other words, a second feedback transistor 262 is provided per one bit line. Therefore, different second feedback transistors 262 are provided for different bit lines. In various embodiments, each second feedback transistor 262 may be controllable by a respective other column signal (e.g. ColBᵢ) associated with the respective resistive memory cell, e.g. the column signal ColBᵢ may control the gate terminal of the respective second feedback transistor 262.

In various embodiments, each second switch 246 of the plurality of second switches 246 may be electrically coupled to an output 264 of the second opamp 254 for controlling the gate terminal of the pass transistor 204 based on a signal from the output 264 of the second opamp 254.

In various embodiments of the writing circuit 250, the controlled voltage source 212 may further include a plurality of control transistors 231, which may be similar to the embodiments as described in the context of FIG. 2B, and the second controlled voltage source 252 may further include a plurality of second control transistors (e.g. second column enabling/disabling transistors) 271, wherein each control transistor 271 is coupled in series with the control transistor 231. For example, each second control transistor 271 includes a first control source/drain terminal, a second control source/drain terminal and a control gate terminal, and wherein the first control source/drain terminal is configured to be electrically coupled to the gate terminal of the pass transistor 204 and the second control source/drain terminal is configured to be electrically coupled to the power supply line (or the first control source/drain terminal of the control transistor 271). In various embodiments, each second control transistor 271 may be controllable by a respective column signal (e.g. ColBᵢ) associated with the respective resistive memory cell, e.g. the column signal ColBᵢ may control the gate terminal of the respective second control transistor 271.

The second opamp 254 may have an inverting input (V₋) and a non-inverting input (V₊), wherein the input 258 may be the non-inverting input (V₊).

In various embodiments, the writing circuit 250 may further include a plurality of discharge circuits 266, wherein each discharge circuit 266 of the plurality of discharge circuits 266 may be configured to be electrically coupled between the bit line associated with the resistive memory cell and a ground terminal. In other words, a discharge circuit 266 is provided per one bit line. Therefore, different discharge circuits 266 are provided for different bit lines.

In various embodiments, each discharge circuit 266 includes a transistor 268 controllable to discharge the bit line after the write operation. The transistor 268 may be controllable by another respective column signal (e.g. ColCᵢ) associated with the respective resistive memory cell. The respective column signal ColCᵢ may be a function of the respective column signal ColAᵢ associated with the same respective resistive memory cell, for example the column signal ColCᵢ is only high and the transistor 268 is enabled for discharging the bit line, immediately after the negative edge or falling edge of ColAᵢ and becomes low again after a short time period.

In various embodiments, each discharge circuit 266 includes a transistor 268 controllable to discharge the bit line after the second write operation. The transistor 268 may be controllable by another respective column signal (e.g. ColCᵢ) associated with the respective resistive memory cell. The respective column signal ColCᵢ may be a function of the respective column signal ColBᵢ associated with the same respective resistive memory cell, for example the column signal ColCᵢ is only high and the transistor 268 is enabled for discharging the bit line, immediately after the negative edge or falling edge of ColBᵢ and becomes low again after a short time period.

In further embodiments, each discharge circuit 266 includes a transistor 268 controllable to discharge the bit line after the write operation, the second write operation and a read operation. In other words, the transistor 268 may be controllable to discharge the bit line after each of the write operation, the second write operation and the read operation has been performed or completed. The transistor 268 may be controllable by another respective column signal (e.g. ColCᵢ) associated with the respective resistive memory cell. The respective column signal ColCᵢ may be a function of a combination of the respective column signal ColAᵢ, the respective column signal ColBᵢ and a respective read enable signal (e.g. RE) associated with the same respective resistive memory cell, for example the column signal ColCᵢ is high and the transistor 268 is enabled for discharging the bit line when the column signal ColAᵢ, the column signal ColBᵢ and the read enable signal RE are low (e.g. ColCᵢ results from an inverse ColAᵢ AND an inverse ColBᵢ AND an inverse RE; ColCᵢ=!ColAᵢ*!ColBᵢ*!RE, where “!” represents an inverse function and “*” represents an AND function).

In other embodiments, each discharge circuit 266 includes three transistors 270 coupled in series to each other, wherein the three transistors 270 are cooperatively controllable to discharge the bit line after the write operation, after the second write operation and after a read operation. In other words, the three series transistors 270 may allow the bit line to be discharged after the write operation and the second write operation and the read operation have been performed or completed. This may ensure that no write operation and/or second write operation and/or read operation is performed during discharging or that discharging operation is not enabled during write operation and/or second write operation and/or read operation.

One of the three series transistors 270 may be controllable by the respective column signal ColAᵢ, another of the three series transistors 270 may be controllable by the respective column signal ColBᵢ, while the remaining of the three series transistors 270 may be controllable by a respective read enable signal (e.g. RE) associated with the same respective resistive memory cell. Therefore, the bit line may be discharged when all of the three series transistors 270 are enabled, for example the discharge operation is a function of an inverse ColAᵢ AND an inverse ColBᵢ AND an inverse RE (e.g. !ColAᵢ*!ColBᵢ*!RE, where “!” represents an inverse function and “*” represents an AND function).

In FIG. 2D, the line represented as 272 is illustrated to show the relationship among the plurality of second switches 246, the second opamp 254, the second feedback circuit 256 and the plurality of second control transistors 271, which may include electrical coupling and/or mechanical coupling, the line represented as 274 is illustrated to show the relationship among the controlled voltage source 212, the second controlled voltage source 252 and the plurality of discharge circuits 266, which may include electrical coupling and/or mechanical coupling, while the line represented as 276 is illustrated to show the relationship between the input 258 and the output 264 of the second opamp 254, which may include electrical coupling and/or mechanical coupling.

In the context of various embodiments, one of or each of the opamp 214 or the second opamp 254 may be or may function as a differential amplifier. Each of the opamp 214 or the second opamp 254 may have an inverting input (V₋) and a non-inverting input (V₊), where the inputs 218, 258 may be the non-inverting input (V₊).

In the context of various embodiments, one of or each of the opamp 214 or the second opamp 254 may be configured as a feedback amplifier or to function as an amplifier to amplify the error voltage between the two voltages applied to its respective two inputs. In various embodiments, an output signal may be provided/generated based on the gain of the difference between the two input voltages to generate the inverting input (V₋) voltage through the feedback circuit 216 or the second feedback circuit 256.

As an example, a “linear” series voltage regulator may include a reference voltage, a means of scaling the regulator output voltage and comparing it to the reference voltage, a feedback amplifier, and a series pass transistor (BJT or FET), whose voltage drop is controlled by the feedback amplifier to maintain the output of the voltage regulator at the required value. If, for example, the load current decreases, causing the output of the voltage regulator to rise incrementally, the error voltage (difference between the reference voltage and the output of the voltage regulator) will increase, causing the amplifier output to rise and the voltage across the pass transistor to increase, thereby returning the output of the voltage regulator to its original value.

In the context of various embodiments, the writing circuits or the voltage regulated writing circuits may maintain the writing voltage applied to the resistive memory cell during the SET and RESET operations (writing operations) even when the writing current is changed and/or the resistance/resistivity of the resistive memory cell is changed.

In the context of various embodiments, the writing circuits or the voltage regulated writing circuits may minimize the effect of the resistance/resistivity distribution of the resistive memory cells, which may otherwise cause a distribution of the write voltage on the resistive memory cells.

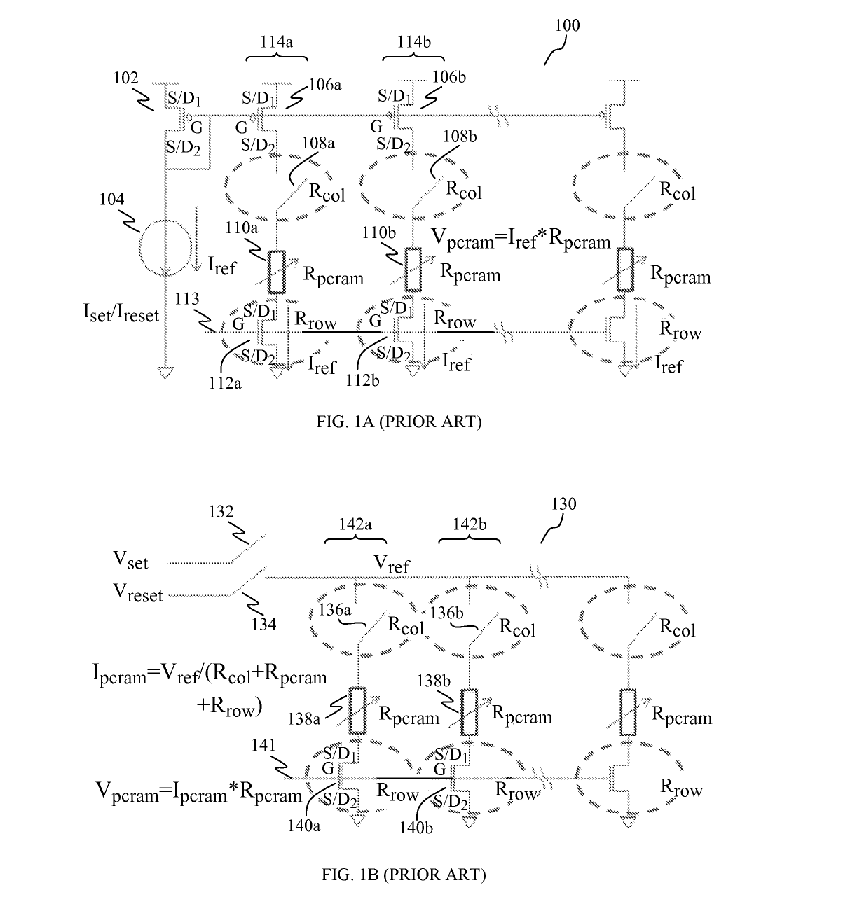

In addition, in the writing circuits or the voltage regulated writing circuits of various embodiments, column selecting switches (e.g. R₁ in the writing circuits illustrated in FIGS. 1A and 1B) may be removed from one or more columns or bit lines associated with the respective resistive memory cells, or the column selecting switches may be removed from each of the column or bit line associated with a resistive memory cell. This may eliminate or minimise the large voltage drop on the respective writing path or bit line, in addition to reducing the power loss on these switches. Furthermore, the loading capacitance on the bit line may be reduced and the reading/writing speed may be increased.

In the context of various embodiments, the writing circuits or the voltage regulated writing circuits may reduce power consumption and the power supply as compared to conventional writing circuits, in addition to finely controlling the voltage on the resistive memory cells, which may become more important in multi-level resistive memory cell writing since the write margin is much smaller than single level writing.

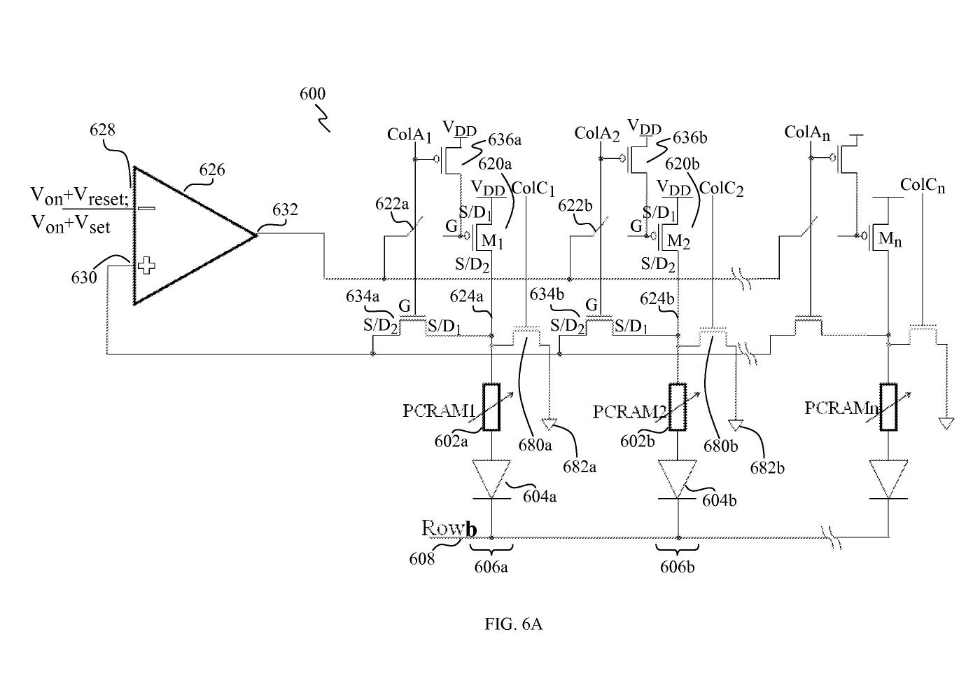

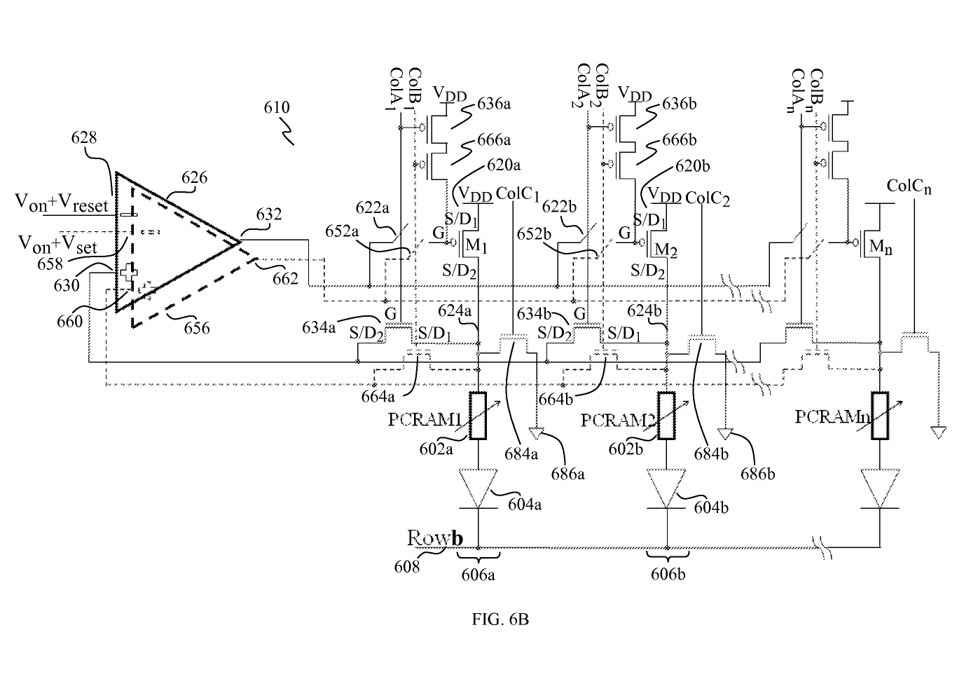

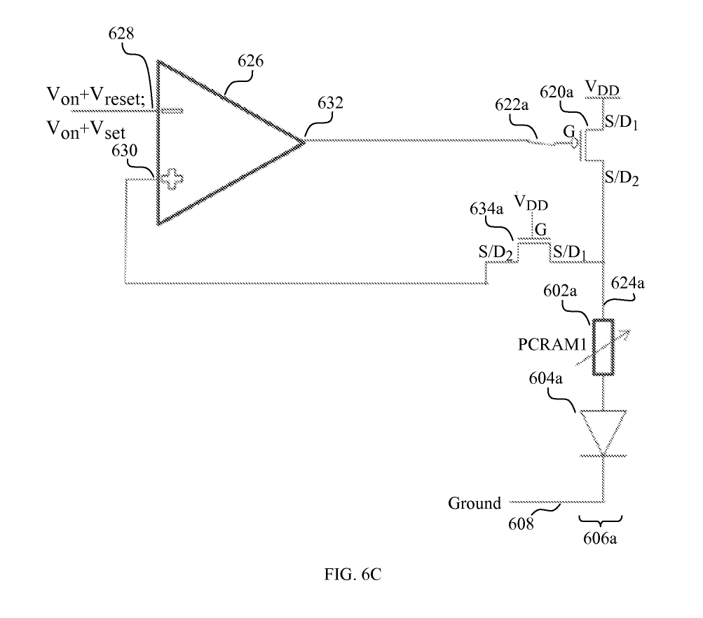

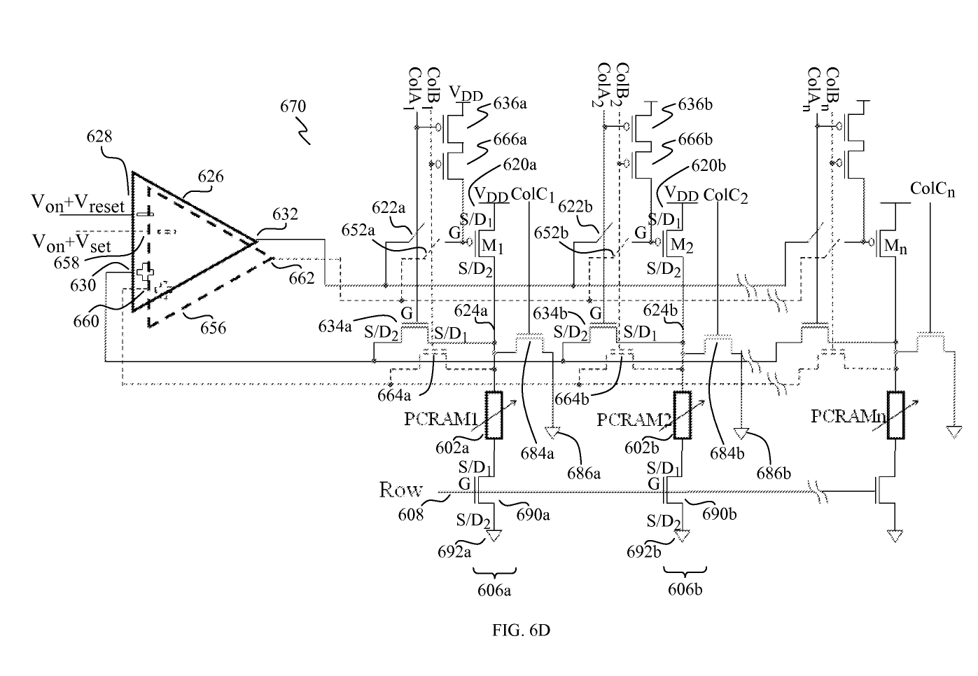

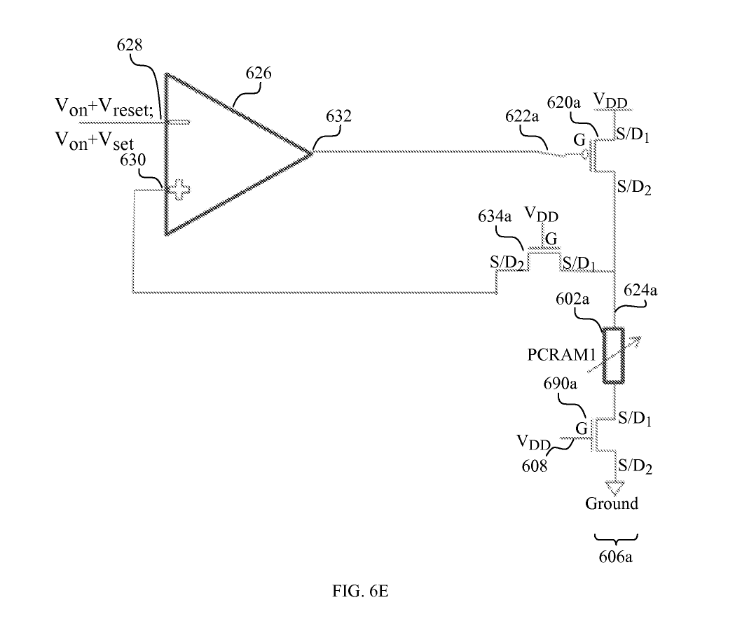

Various embodiments of the writing circuits or architectures may be used or employed in a memory cell arrangement having a 1T1R architecture or a 1D1R architecture. A 1T1R (1-transistor 1-resistor) architecture refers to an architecture having one transistor (1T) (e.g. 690a, FIG. 6D) and one resistor (1R) in the form of the resistive memory cell (e.g. 602a, FIG. 6D). A 1D1R (1-diode 1-resistor) architecture refers to an architecture having one diode (1D) (e.g. 604a, FIG. 6B) and one resistor (1R) in the form of the resistive memory cell (e.g. 602a, FIG. 6B).

FIG. 2E shows a schematic block diagram of a memory cell arrangement 280, according to various embodiments. The memory cell arrangement 280 includes a plurality of resistive memory cells 281, and a writing circuit 282 for the plurality of resistive memory cells 281, the writing circuit 282 including a controlled voltage source 283 including a plurality of pass transistors (or biasing transistors) 284, wherein each pass transistor 284 includes a first source/drain terminal, a second source/drain terminal and a gate terminal, and wherein the first source/drain terminal is configured to be electrically coupled to a power supply line and the second source/drain terminal is configured to be electrically coupled to a bit line associated with a resistive memory cell 281 of the plurality of resistive memory cells 281, and a plurality of switches 285, wherein each switch 285 is configured to control the gate terminal of the pass transistor 284, wherein the controlled voltage source 283 is configured to supply a voltage to the resistive memory cell 281 for a write operation.

In other words, the controlled voltage source 283 includes a plurality of pass transistors 284 and a plurality of switches 285, where a pass transistor 284 and a switch 285 are provided per one bit line. Therefore, different pass transistors 284 and different switches 285 are provided for different bit lines.

In FIG. 2E, the line represented as 288 is illustrated to show the relationship between the plurality of pass transistors 284 and the plurality of switches 285, which may include electrical coupling and/or mechanical coupling, while the line represented as 289 is illustrated to show the relationship between the plurality of resistive memory cells 281 and the writing circuit 282, which may include electrical coupling and/or mechanical coupling.

It should be appreciated that the writing circuit 282 may be similar to the writing circuit 200 as described in the context of FIG. 2A.

FIG. 2F shows a schematic block diagram of a memory cell arrangement 290, according to various embodiments. The memory cell arrangement 290 includes a plurality of resistive memory cells 281, which may be similar to the embodiments as described in the context of FIG. 2E, and a writing circuit 291 including a controlled voltage source 292. The controlled voltage source 292 includes a plurality of pass transistors 284 and a plurality of switches 285, which may be similar to the embodiments as described in the context of FIG. 2E.

The controlled voltage source 292 may further include an opamp 293 for regulating the voltage during the write operation.

In various embodiments, the controlled voltage source 292 may further include a feedback circuit 294 configured to be electrically coupled to an input 295 of the opamp 293 and the plurality of resistive memory cells 281. The opamp 293 may include an output 296.

In FIG. 2F, the line represented as 297 is illustrated to show the relationship between the input 295 and the output 296 of the opamp 293, which may include electrical coupling and/or mechanical coupling, the line represented as 298 is illustrated to show the relationship among the plurality of pass transistors 284, the plurality of switches 285, the opamp 293 and the feedback circuit 294, which may include electrical coupling and/or mechanical coupling, while the line represented as 299 is illustrated to show the relationship between the plurality of resistive memory cells 281 and the writing circuit 291, which may include electrical coupling and/or mechanical coupling.

It should be appreciated that the plurality of pass transistors 284, the plurality of switches 285, the opamp 293 and the feedback circuit 294 may be similar to the plurality of pass transistors 204, the plurality of switches 206, the opamp 214 and the feedback circuit 216 respectively as described in the context of FIGS. 2A and 2B.

While not shown in FIG. 2F, it should be appreciated that a plurality of control transistors similar to the plurality of control transistors 231 as described in the context of FIG. 2B may be provided in the controlled voltage source 292. Therefore, it should be appreciated that the controlled voltage source 292 may be similar to the controlled voltage source 212 as described in the context of FIG. 2B.

While not shown in FIG. 2F, it should be appreciated that a discharge circuit similar to the discharge circuit 226 as described in the context of FIG. 2B may be provided in the writing circuit 291. Therefore, it should be appreciated that the writing circuit 291 may be similar to the writing circuit 210 as described in the context of FIG. 2B.

In the context of various embodiments, a memory cell arrangement including a plurality of resistive memory cells and a writing circuit for the plurality of resistive memory cells may be provided. The writing circuit may be similar to any one of the embodiments of the writing circuits 200, 210, 240 and 250 as described respectively in the context of FIGS. 2A, 2B, 2C and 2D.

In the context of various embodiments of the memory cell arrangement (e.g. 280, 290), the memory cell arangement (e.g. 280, 290) may further include a plurality of diodes, wherein a diode of the plurality of diodes is electrically coupled between the resistive memory cell (e.g. 281) and a word line of the memory cell arrangement (e.g. 280, 290). In other words, a diode may be provided or associated per one resistive memory cell (e.g. 281), thereby providing a 1D1R circuit or architecture. In various embodiments, the word line may be grounded.

In the context of various embodiments of the memory cell arrangement (e.g. 280, 290), the memory cell arangement (e.g. 280, 290) may further include a plurality of transistors, wherein a transistor of the plurality of transistors is electrically coupled between the resistive memory cell (e.g. 281) and a ground terminal, and wherein the transistor is controllable by a word line of the memory cell arrangement (e.g. 280, 290) via its gate terminal. In other words, a transistor may be provided or associated per one resistive memory cell (e.g. 281), thereby providing a 1T1R circuit or architecture.

In the context of various embodiments, the term “memory cell arrangement” may be interchangably referred to as “memory” or “memory device”.

In the context of various embodiments, writing into each target resistive memory cell (e.g. 281) of the plurality of resistive memory cells (e.g. 281) may be performed sequentially or simultaneously.

In the context of various embodiments, where the writing circuit includes one (single) controlled voltage source (e.g. 202, 212, 283, 292), the controlled voltage source (e.g. 202, 212, 283, 292), with the corresponding pass transistors (e.g. 204, 284) and/or switches (e.g. 206, 285) and/or opamp (e.g. 214, 293) and/or feedback circuit (e.g. 216, 294) and/or plurality of control transistors (e.g. 231), may be configured to perform a SET operation and a RESET operation. Therefore, one or more or all of the plurality of resistive memory cells (e.g. 281) may be written to logic state ‘1’ (SET) sequentially or simultaneously at one time or to logic state ‘0’ (RESET) sequentially or simultaneously at another time, using the controlled voltage source.

In the context of various embodiments, where the writing circuit includes a first controlled voltage source (e.g. 202, 212, 283, 292) and a second controlled voltage source (e.g. 242, 252), the first controlled voltage source (e.g. 202, 212, 283, 292), with the corresponding pass transistors (e.g. 204, 284) and/or switches (e.g. 206, 285) and/or opamp (e.g. 214, 293) and/or feedback circuit (e.g. 216, 294) and/or plurality of control transistors (e.g. 231), may be configured to perform the SET operation while the second controlled voltage source (e.g. 242, 252), with the corresponding second switches (e.g 246) and/or second opamp (e.g. 254) and/or second feedback circuit (e.g. 256) and/or plurality of second control transistors (e.g. 271), may be configured to perform the RESET operation, or vice versa. Therefore, one or more of the plurality of resistive memory cells (e.g. 281) may be written to logic state ‘1’ (SET) sequentially or simultaneously and one or more of the plurality of resistive memory cells (e.g. 281) may be written to logic state'0′ (RESET) sequentially or simultaneously, at the same time, using both the first controlled voltage source and the second controlled voltage source simultaneously.

In the context of various embodiments, one or more of the plurality of switches 206, 285 and/or one or more of the plurality of second switches 246 may include or may be a transistor.

In the context of various embodiments, the term “controlled voltage source” may mean a voltage source in which the voltage across the voltage source may be determined by some other voltage or current in a circuit.

In the context of various embodiments, each of the first controlled voltage source (e.g. 202, 212, 283, 292) and the second controlled voltage source (e.g. 242, 252) may act as a regulator, e.g. a voltage regulator.

In the context of various embodiments, the term “resistive memory cell” may include a memory cell of any kind which may be switched between two or more states exhibiting different resistivity values.

In the context of various embodiments, the resistive memory cell (e.g. 281) may be a magnetoresistive memory cell. The resistive memory cell (e.g. 281) may also be but not limited to a resistive random-access memory (RRAM) cell, a phase change random-access memory (PCRAM) cell, a conductive bridging random-access memory (CBRAM) cell, a magnetoresistive random-access memory (MRAM) cell or a redox-based resistive switching memory cell.

It should be appreciated that in some embodiments, where the writing circuit includes a first controlled voltage source and a second controlled voltage source, the first controlled voltage source, with the corresponding pass transistors and/or switches and/or opamp and/or feedback circuit and/or plurality of control transistors, may be coupled to the bit lines and configured to perform the SET operation, while the second controlled voltage source, with the corresponding second switches and/or second opamp and/or second feedback circuit and/or plurality of second control transistors, may be coupled to the source lines and configured to perform the RESET operation.

In the context of various embodiments, the resistive memory cell (e.g. 281) may be a phase change memory cell or phase-change random access memory (PCRAM) cell. The phase change memory cell may include a resistivity changing material. The resistivity changing material may be configured to change from an amorphous phase to a crystalline phase and from a crystalline phase to an amorphous phase. A phase change (e.g. from amorphous phase/state to crystalline phase/state or vice versa) in the resistivity changing material of the resistive memory cell may cause a change in the resistivity of the resistivity changing material. The resistance of the resistivity changing material and therefore also that of the resistive memory cell may be changed as a result of the change in the resistivity of the resistivity changing material. For example, the resistivity changing material in the amorphous phase may have a higher resistivity compared to the resistivity of the resistivity changing material in the crystalline phase. Accordingly, the resistivity changing material in the amorphous phase may have a higher resistance compared to the resistance of the resistivity changing material in the crystalline phase.

In the context of various embodiments, the resistivity changing material may be a phase change material or the resistive memory cell (e.g. 281) may include a phase change material. The phase change material may include a chalcogenide or an alloy of chalcogenides. The chalcogenide or alloy of chalcogenides may include tellurium, selenium or a combination thereof. In various embodiments, the phase change material or the chalcogenide material may include germanium-tellurium (GeTe), indium-selenium (InSe), antimony-selenium (SbSe), antimony-tellurium (SbTe), tellurium-arsenic-germanium (TeAsGe), tellurium-selenium-sulphur (TeSeS), tellurium-selenium-antimony (TeSeSb), indium-antimony-tellurium (InSbTe), germanium-antimony-tellurium (GeSbTe), tellurium-germanium-tin (TeGeSn), silver-indium-antimony-tellurium (AgInSbTe), indium-antimony-selenium (InSbSe), indium-antimony-tellurium (InSbTe), germanium-antimony-selenium (GeSbSe), germanium-antimony-tellurium-selenium (GeSbTeSe), silver-indium-antimony-selenium-tellurim (AgInSbSeTe) or a combination thereof.

In the context of various embodiments, the phase change material may include a dopant. It should be appreciated that one or more types of dopant elements may be provided in the phase change material. In various embodiments, the dopant may be selected from a group consisting of germanium (Ge), tellurium (Te), antimony (Sb), silver (Ag), indium (In), chromium (Cr), nitrogen (N), selenium (Se), tin (Sn), silicon (Si), bismuth (Bi) and any combinations thereof. However, it should be appreciated that other dopants may be used.

In the context of various embodiments, the phase change memory cell may switch between a crystalline phase and an amorphous phase during the SET and RESET operations. An electrical signal, e.g. a current, a voltage, may be applied to the phase change memory cell for generation of Joule heat to alternate the phase change material between these two phases. During the SET operation, the phase change material may be heated above its crystallization temperature for a sufficiently long time to convert it from an amorphous phase to the crystalline phase. On the other hand, during the RESET operation, switching from the crystalline phase to the amorphous phase may be accomplished by raising the temperature above the melting point followed by rapid quenching. The higher temperature needed for the RESET operation requires an electrical signal of a larger amplitude.

In various embodiments, in order to change from an amorphous phase to a crystalline phase (i.e. the SET operation), the electrical signal applied to the resistivity changing material or phase change material may be a pulse (e.g. a voltage pulse) having a duration in a range of between about 0.1 ns and about 1000 ns, for example between about 0.1 ns and about 500 ns, between about 0.1 ns and about 100 ns, between about 0.1 ns and about 50 ns, between about 100 ns and about 1000 ns, or between about 500 ns and about 1000 ns. The pulse applied may have an amplitude in a range of between about 0.5 V and about 1.5 V, for example between about 0.5 V and about 1.0 V or between about 1.0 V and about 1.5 V.

In various embodiments, in order to change from a crystalline phase to an amorphous phase (i.e. the RESET operation), the electrical signal applied to the resistivity changing material or phase change material may be a pulse (e.g. a voltage pulse) having a duration in the range of between about 0.1 ns and about 100 ns, for example between about 0.1 ns and about 50 ns, between about 0.1 ns and about 10 ns, between about 0.1 ns and about 5 ns, between about 10 ns and about 100 ns, or between about 50 ns and about 100 ns. The pulse applied may have an amplitude in the range of between about 1.5 V and about 5 V, for example between about 1.5 V and about 3.0 V, between about 1.5 V and about 2.0 V, or between about 3.0 V and about 5 V.

In the context of various embodiments, the term “transistor” may mean a bipolar junction transistor (BJT) or a field effect transistor (FET), such as one of a metal oxide semiconductor field effect transistor (MOSFET) (e.g. an re-channel MOS transistor (NMOS), a p-channel MOS transistor (PMOS)), a metal-insulator field effect transistor (MISFET) or a metal-semiconductor field effect transistor (MESFET).

In the context of various embodiments, the term “source/drain terminal” of a transistor may refer to a source terminal or a drain terminal. As the source terminal and the drain terminal of a transistor are generally fabricated such that these terminals are geometrically symmetrical, these terminals may be collectively referred to as source/drain terminals. In various embodiments, a particular source/drain terminal may be a “source” terminal or a “drain” terminal depending on the voltage to be applied to that terminal. Accordingly, the terms “first source/drain terminal” and “second source/drain terminal” may be interchangeable.

In the context of various embodiments, the plurality of control transistors 231 and/or the plurality of second control transistors 271 may pull up the gate of the respective pass transistor (e.g. 204, 284) (i.e. to increase the voltage at the gate terminal of the respective pass transistor to a higher value) when the pass transistor is dis-selected in order to avoid or minimise leakage in the pass transistor.

In the context of various embodiments, the terms “control” and “controllable” may include biasing, enabling or disabling, activating or deactivating, switching on or switching off and turning on or turning off. For example, where the gate terminal of a transistor is controlled, the gate terminal and therefore the transistor may be enabled or disabled to respectively allow a current to pass through, for example via a conduction channel formed between the source terminal and the drain terminal of the transistor, or disallow a current to pass through the transistor. The terms “control” and “controllable” may be interchangeably used with the terms “address” and “addressable” respectively.

In the context of various embodiments, the terms “couple” and “coupled” may include electrical coupling which may allow a current to flow, and/or mechanical coupling.

In the context of various embodiments, the term “bit line” of a memory cell arrangement may refer to a data line of the memory cell arrangement.

In the context of various embodiments, a resistive memory cell of the memory cell arrangement may be accessed or addressed by its row-number and column-number. The rows may also be known as the word lines and the columns may also be known as the bit lines.

Various embodiments relate to resistive memory cells and memory arrangements, for example phase change memory. Phase-change memory (also known as PCME, PRAM, PCRAM, Ovonic Unified Memory, Chalcogenide RAM and C-RAM) is a type of non-volatile computer memory. PCRAMs exploit the unique behavior of chalcogenide glass. With the application of heat produced, for example, by the passage of an electric signal (e.g. current), the chalcogenide material may be “switched” between two states; crystalline and amorphous. The crystalline and amorphous states of chalcogenide glass have different electrical resistivities, which form the basis by which data may be stored in phase change memory. The amorphous phase having a high resistance state may be used to represent a binary or logic state ‘0’, while the crystalline phase having a low resistance state may be used to represent a binary or logic state ‘1’.

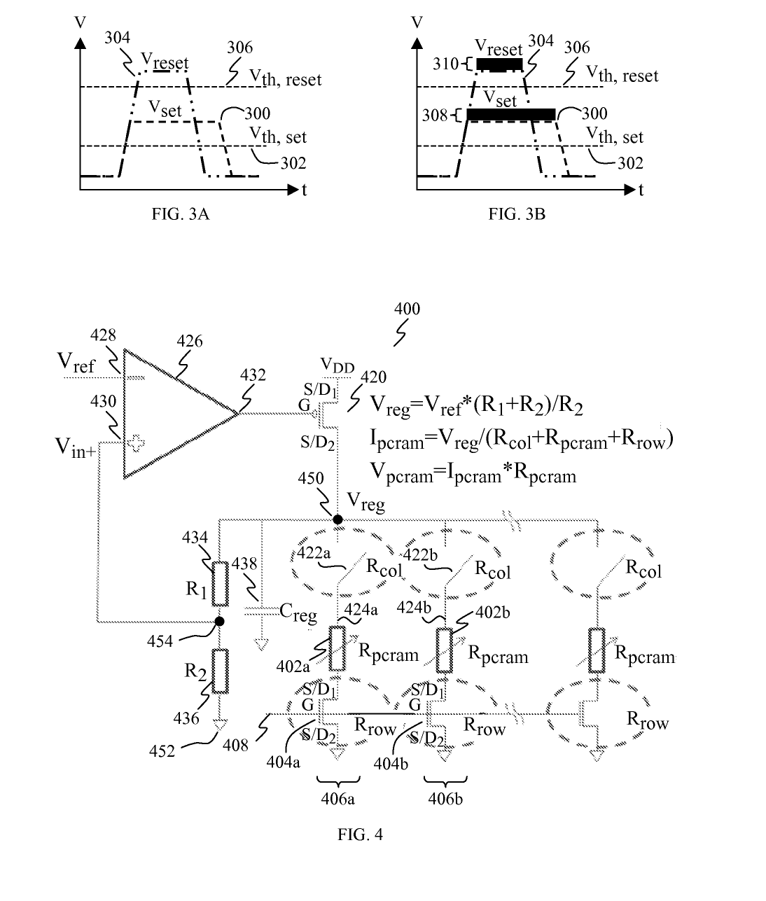

FIG. 3A shows a schematic diagram of writing voltages to SET/RESET the resistive memory cells, according to various embodiments. During a SET operation in order to switch from the amorphous phase to the crystalline phase to write a logic state ‘1’, a SET voltage pulse, Vₛₑₜ, 300 having a medium voltage and long pulse may be imposed or applied on the resistive memory cell or the PCRAM cell. The SET voltage Vₛₑₜ 300 has an amplitude higher than a SET threshold voltage, V_{th, set}, 302 necessary to induce change from the amorphous phase to the crystalline phase. The SET pulse, Vₛₑₜ, 300 may have a duration in the range of between about 0.1 ns and about 1000 ns, for example between about 0.1 ns and about 500 ns, between about 0.1 ns and about 100 ns, between about 0.1 ns and about 50 ns, between about 100 ns and about 1000 ns, or between about 500 ns and about 1000 ns, and/or an amplitude in the range of between about 0.5 V and about 1.5 V, for example between about 0.5 V and about 1.0 V or between about 1.0 V and about 1.5 V.

During a RESET operation in order to switch from the crystalline phase to the amorphous phase to write a logic state ‘0’, a RESET voltage pulse, Vᵣₑₛₑₜ, 304 having a high voltage and short pulse may be imposed or applied on the resistive memory cell or the PCRAM cell. The RESET voltage Vᵣₑₛₑₜ 304 has an amplitude higher than a RESET threshold voltage, V_{th, reset}, 306 necessary to induce change from the crystalline phase to the amorphous phase. The RESET pulse, Vᵣₑₛₑₜ, 304 may have a duration in the range of between about 0.1 ns and about 100 ns, for example between about 0.1 ns and about 50 ns, between about 0.1 ns and about 10 ns, between about 0.1 ns and about 5 ns, between about 10 ns and about 100 ns, or between about 50 ns and about 100 ns, and/or an amplitude in the range of between about 1.5 V and about 5 V, for example between about 1.5 V and about 3.0 V, between about 1.5 V and about 2.0 V, or between about 3.0 V and about 5 V.

In both the crystalline state and the amorphous state, the resistivity and therefore the resistance of the resistive memory cell (e.g. PCRAM cell) may be changed with the voltage applied on or across the PCRAM cell, where the resistance, R, may be empirically derived and may be expressed as R=K*e^{-aV}, where the parameters K and a are constants and depend on the state or phase of the PCRAM cell and the material used for the PCRAM cell, and V is the reading voltage. As the resistance of the PCRAM cell is changed during SET/RESET, the voltage on the PCRAM cell also changes.

As shown in FIG. 3B, by maintaining a SET writing voltage, Vₛₑₜ, 300 between V_{th, set} 302 and V_{th, reset} 306, for example any value within the region 308, and a RESET writing voltage, Vᵣₑₛₑₜ 1304 larger than V_{th, reset} 306, for example any value within the region 310, any effects on the respective SET and RESET writing voltage levels due to the change in the resistivity/resistance of the PCRAM cell, noise, disturbance or resistance distribution, may be minimised. As described in relation to FIGS. 1A and 1B, the voltage across the PCRAM cell, V_{pcram}(=I_{pcram}×R_{pcram} or V×R_{pcram}/(R_{col}+R_{pcram}+R_{row})) is uncertain, therefore the SET writing voltage level and/or RESET writing voltage level applied may not be the respective voltage levels required and therefore the respective writing voltages may need to be manually tuned, for example in a range within the respective regions 308, 310.

FIG. 4 shows a schematic of a writing circuit 400, according to various embodiments, for a resistive memory cell arrangement. The resistive memory cell arrangement may include a plurality of resistive memory cells (e.g. PCRAM cells), e.g. 402a, 402b, respectively coupled to a plurality of row selecting transistors, e.g. 404a, 404b in the respective columns, e.g. 406a, 406b. Each resistive memory cell 402a, 402b has a resistance R_{pcram}/while each row selecting transistor 404a, 404b has a resistance R_{row}.

A first source/drain terminal (S/D₁) of a row selecting transistor, e.g. 404a, 404b is coupled to a resistive memory cell, e.g. 402a, 402b, a second source/drain terminal (S/D₂) of the row selecting transistor 404a, 404b is coupled to ground while the gate terminal (G) of the transistor 404a, 404b is coupled to a word line 408.

The writing circuit 400 includes a controlled voltage source including a pass transistor 420 and a plurality of column selecting switches, e.g. 422a, 422b, each switch 422a, 422b being coupled to a bit line, e.g. 424a, 424b and the resistive memory cell 402a, 402b. Each column selecting switch 422a, 422b has a resistance R_{c01}. The controlled voltage source further includes an opamp 426 having an inverting input (V₋) 428, a non-inverting input (V₊) 430 and an output 432, and a feedback circuit of a voltage divider having two resistors, R₁ 434 and R₂ 436 coupled in series. The controlled voltage source may further include a regulating capacitor, C_{reg} 438.

The first source/drain terminal (S/D₁) of the pass transistor 420 is coupled to a power supply line, V_{DD}, the second source/drain terminal (S/D₂) of the pass transistor 420 is coupled to the plurality of column selecting switches 422a, 422b, the feedback circuit of R₁ 434 and R₂ 436, and the regulating capacitor, C_{reg} 438, for example via a common node 450, while the gate terminal (G) of the pass transistor 420 is coupled to the output 432 of the opamp 426.

The feedback circuit of R₁ 434 and R₂ 436 is connected between the plurality of resistive memory cells 402a, 402b (e.g. connected or electrically coupled to the common node 450 connected or electrically coupled to the plurality of resistive memory cells 402a, 402b) and a ground or a voltage terminal 452, with the non-inverting input (V₊) 430 of the opamp 426 connected or electrically coupled to a node 454 located between R₁ 434 and R₂ 436.

In operation, a voltage V_{ref} may be provided to the inverting input (V₋) 428, and a voltage V_{reg} may be generated at the common node 450 located prior to the plurality of column selecting switches 422a, 422b. The voltage V_{reg} is fed back via the feedback circuit of R₁ 434 and R₂ 436 to the non-inverting input (V₊) 430 of the opamp 426 as Vᵢₙ₊(=V_{reg}(R₂/R₁+R₂)). The opamp 426 may act as a feedback amplifier to amplify the error voltage between V_{ref} and Vᵢₙ₊ and based on this amplification of the difference between V_{ref} and Vᵢₙ₊ produces an output signal at the output 432, which may control the gate terminal (G) of the pass transistor 420 for regulating the voltage V_{reg}. When the fed back voltage, is at least substantially equal to V_{ref}, the voltage V_{reg} may be regulated at V_{ref}(R₁+R₂/R₂). Using the column 406a as a non-limiting example, when the switch 422a is closed, the current, I_{pcram}, passing through the resistive memory cell 402a and the bit line 424a is (V_{reg}/(R_{col}+R_{pcram}+R_{row})), as the column selecting switch 422a, the resistive memory cell 402a and the transistor 404a are coupled in series.

While the writing circuit 400 may provide a regulated voltage to each column 406a, 406b, there are challenges in that the resistive memory cells 402a, 402b may require a large writing current to change the resistive levels (e.g. by changing the material phases) of the resistive memory cells 402a, 402b. For example, during RESET, the writing current may be about 0.1 mA to 2 mA, and as each column selecting switch 422a, 422b may have a high resistance (e.g. ≧1 kΩ), the voltage drop on or across the column selecting switches 422a, 422b may be larger than 1 V. As a result of the large resistance of the column selecting switches 422a, 422b, it may not be possible to make sure the writing voltage on the resistive memory cells 402a, 402b or that the writing voltage level applied on the resistive memory cells 402a, 402b may change and may not be the voltage levels required for the write operation.

In order to reduce the effect of the column selecting switches 422a, 422b, one approach is to increase the W/L ratio of the column selecting switches 422a, 422b, where the column selecting switches 422a, 422b are transistors, in order to reduce the corresponding resistance of the column selecting switches 422a, 422b. The parameter L is the channel length, referring to the distance from the drain terminal to the source terminal while the parameter W is the lateral dimension in the form of the channel width. The W/L ratio is related to the drain current capability, for example a larger W passes more current and therefore reduces the resisrance.

However, as the resistance of the resistive memory cells 402a, 402b may be small (e.g. <1 kΩ) during writing, if the voltage drop effect from the column selecting switches 422a, 422b is to be minimised or omitted, the resistance of the column selecting switches 422a, 422b should be much smaller (e.g. <<1 kΩ) than that of the resistive memory cells 402a, 402b. This may require column selecting switches 422a, 422b with a very large W/L ratio, which may increase the size of the memory chip and reduce the reading/writing speed, in addition to requiring a higher voltage power supply and high power consumption by the column selecting switches 422a, 422b.

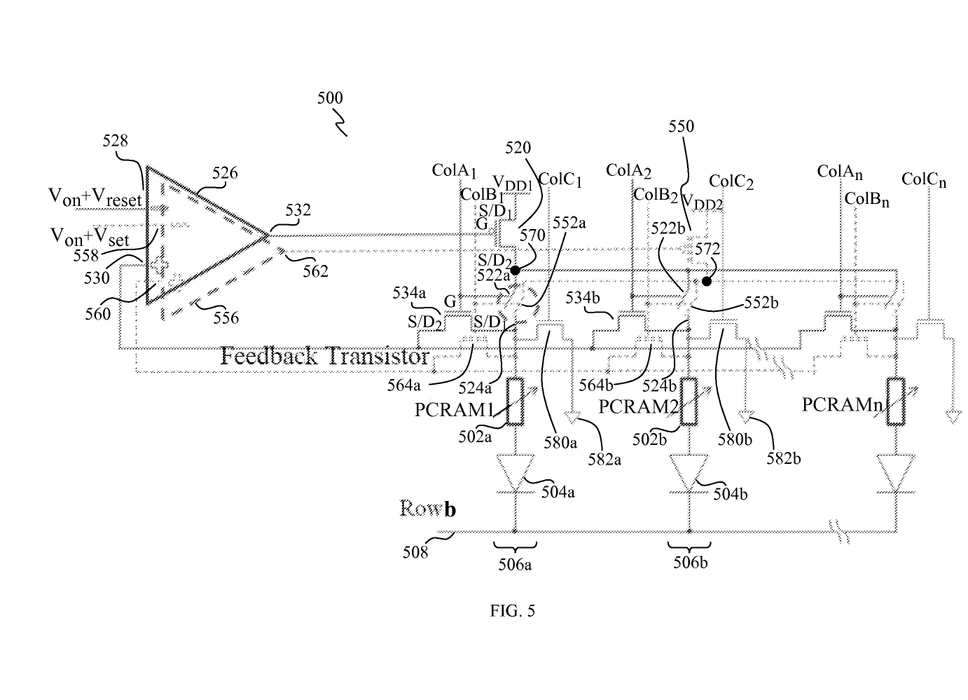

FIG. 5 shows a schematic of a writing circuit 500, according to various embodiments, for a resistive memory cell arrangement. The resistive memory cell arrangement may include a plurality of resistive memory cells (e.g. PCRAM cells), e.g. PCRAM1 502a, PCRAM2 502b, respectively coupled in series to a plurality of diodes, e.g. 504a, 504b in the respective columns, e.g. 506a, 506b. The plurality of diodes 504a, 504b are also coupled to a word line 508. As one diode 504a, 504b is associated or coupled with a resistive memory cell 502a, 502b, the resistive memory cell arrangement has a 1D1R architecture. In various embodiments, the word line 508 may be selected when the word line 508 is set to logic ‘0’ (e.g. Rowb=0).

The writing circuit 500 includes a controlled voltage source including a pass transistor 520 and a plurality of column selecting switches, e.g. 522a, 522b, each switch 522a, 522b being configured to couple to a bit line, e.g. 524a, 524b and the resistive memory cell 502a, 502b. Each column selecting switch 522a, 522b has a resistance R_{col}. The controlled voltage source further includes an opamp 526 having an inverting input (V₋) 528, a non-inverting input (V₊) 530 and an output 532, and a feedback circuit including a plurality of feedback transistors (e.g. NMOS transistors), e.g. 534a, 534b, electrically coupled to the non-inverting input (V₊) 530 of the opamp 526 and the respective bit lines 524a, 524b associated with the respective resistive memory cells 502a, 502b to feed back the voltage at the respective bit lines 524a, 524b to the non-inverting input (V₊) 530 of the opamp 526.

The first feedback source/drain terminal (S/D₁) of each feedback transistor 534a, 534b is electrically coupled to the bit line 524a, 524b associated with the respective resistive memory cells 502a, 502b and the second feedback source/drain terminal (S/D₂) of each feedback transistor 534a, 534b is electrically coupled to the non-inverting input (V₊) 530 of the opamp 526. The gate terminal (G) of each feedback transistor 534a, 534b may be controllable or addressable by a respective column signal (ColA₁, ColA₂, . . . , ColAₙ). The respective column signal (ColA₁, ColA₂, . . . , ColAₙ) may also be employed to control (e.g. open and close) the respective column selecting switches 522a, 522b.

The first source/drain terminal (S/D₁) of the pass transistor 520 is coupled to a power supply line, V_{DD1}, the second source/drain terminal (S/D₂) of the pass transistor 520 is coupled to the plurality of column selecting switches 522a, 522b, and the first feedback source/drain terminals (S/D₁) of the plurality of feedback transistors 534a, 534b, while the gate terminal (G) of the pass transistor 520 is coupled to the output 532 of the opamp 526.

In operation, using the example that the controlled voltage source is configured for the RESET operation, a voltage Vₒₙ+Vᵣₑₛₑₜ may be provided to the inverting input (V₋) 528 of the opamp 526, and a voltage V_{node,1} may be generated at the common node 570. Vₒₙ is the turn on voltage of the diodes 504a, 504b, and Vᵣₑₛₑₜ is the RESET voltage for the resistive memory cells 502a, 502b. The voltage, V_{reg,1}, at each bit line 524a, 524b, after the respective column selecting switches 522a, 522b, where (V_{reg,1}=V_{node,1}—voltage drop across a column selecting switch 522a, 522b) is fed back via the respective feedback transistors 534a, 534b to the non-inverting input (V₊) 530 of the opamp 526 as V_{in,1}. The opamp 526 may act as a feedback amplifier to amplify the voltage difference between (Vₒₙ+Vᵣₑₛₑₜ) and V_{in+,1} and based on this amplification, produces an output signal at the output 532, which may control (bias) the gate terminal (G) of the pass transistor 520 for regulating the voltage V_{reg,1}. When the fed back voltage, V_{in+,1}, is at least substantially equal to (Vₒₙ+Vᵣₑₛₑₜ), the voltage V_{reg,1} may be regulated at (Vₒₙ+Vᵣₑₛₑₜ). Using the column 506a as a non-limiting example, when the switch 522a is closed, the voltage, V_{pcram}, across the resistive memory cell 502a may be regulated at Vᵣₑₛₑₜ, as Vₒₙ is at least substantially stable, even with different currents, when the diode 504a is turned on. It should be appreciated that the controlled voltage source may be configured instead for the SET operation.

The writing circuit 500 may further include a second controlled voltage source including a second pass transistor 550 and a plurality of second column selecting switches, e.g. 552a, 552b, each second column selecting switch 552a, 552b being configured to couple to the bit line, e.g. 524a, 524b and the resistive memory cell 502a, 502b. Each second column selecting switch 552a, 552b has a resistance R_{col}. The second controlled voltage source further includes a second opamp 556 having an inverting input (V₋) 558, a non-inverting input (V₊) 560 and an output 562, and a second feedback circuit including a plurality of second feedback transistors (e.g. NMOS transistors), e.g. 564a, 564b, electrically coupled to the non-inverting input (V₊) 560 of the second opamp 556 and the respective bit lines 524a, 524b associated with the respective resistive memory cells 502a, 502b to feed back the voltage at the respective bit lines 524a, 524b to the non-inverting input (V₊) 560 of the second opamp 556.

The first feedback source/drain terminal (S/D₁) of each second feedback transistor 564a, 564b is electrically coupled to the bit line 524a, 524b associated with the respective resistive memory cells 502a, 502b and the second feedback source/drain terminal (S/D₂) of each second feedback transistor 564a, 564b is electrically coupled to the non-inverting input (V₊) 560 of the second opamp 556. The gate terminal (G) of each second feedback transistor 564a, 564b may be controllable or addressable by a respective column signal (ColB₁, ColB₂, . . . , ColBₙ). The respective column signal (ColB₁, ColB₂, . . . , ColBₙ) may also be employed to control (e.g. open and close) the respective second column selecting switches 552a, 552b.

The first source/drain terminal (S/D₁) of the second pass transistor 550 is coupled to a power supply line, V_{DD2}, the second source/drain terminal (S/D₂) of the second pass transistor 550 is coupled to the plurality of second column selecting switches 552a, 552b, and the first feedback source/drain terminals (S/D₁) of the plurality of second feedback transistors 564a, 564b, while the gate terminal (G) of the second pass transistor 550 is coupled to the output 562 of the second opamp 556. The power supply line, V_{DD2} may be the same as the power supply line, V_{DD1}.

In operation, using the example that the second controlled voltage source is configured for the SET operation, a voltage (Vₒₙ+Vₛₑₜ) may be provided to the inverting input (V₋) 558 of the second opamp 556, and a voltage V_{node,2} may be generated at the common node 572. Vₒₙ is the turn on voltage of the diodes 504a, 504b, and Vₛₑₜ is the SET voltage for the resistive memory cells 502a, 502b. The voltage, V_{reg,2}, at each bit line 524a, 524b, after the respective second column selecting switches 552a, 552b, where (V_{reg,2}=V_{node,2} voltage drop across a second column selecting switch 552a, 552b) is fed back via the respective second feedback transistors 564a, 564b to the non-inverting input (V₊) 560 of the second opamp 556 as V_{in+,2}. The second opamp 556 may act as a feedback amplifier to amplify the error voltage between (Vₒₙ+Vₛₑₜ) and V_{in+,2} and based on this amplification of the difference between (Vₒₙ+Vₛₑₜ) and V_{in+,2}, produces an output signal at the output 562, which may control the gate terminal (G) of the second pass transistor 550 for regulating the voltage V_{reg,2}. When the fed back voltage, V_{in+,2}, is at least substantially equal to (Vₒₙ+Vₛₑₜ), the voltage V_{reg,2} may be regulated at (Vₒₙ+Vₛₑₜ). Using the column 506b as a non-limiting example, when the second switch 552b is closed, the voltage, V_{pcram}, across the resistive memory cell 502b may be regulated at Vₛₑₜ, as Vₒₙ is at least substantially stable, even with different currents, when the diode 504b is turned on. It should be appreciated that the second controlled voltage source may be configured instead for the RESET operation.

It should be appreciated that the two controlled voltage sources may have a similar architecture and/or may be operated in a similar fashion for writing to the plurality of resistive memory cells 502a, 502b. Either of the two controlled voltage sources may be configured for either the SET write operation or the RESET write operation, as long as the two controlled voltage sources are configured for different write operations.

By having two controlled voltage sources, respectively including a pass transistor, an opamp, a feedback circuit and a plurality of column selecting switches, the plurality of resistive memory cells 502a, 502b may be written in parallel, with one or more resistive memory cells 502a, 502b written to the logic state ‘1’ (SET operation), and one or more resistive memory cells 502a, 502b written to the logic state ‘0’ (RESET operation).

As a non-limiting example of writing a logic ‘0’ to the resistive memory cell 502a, the column signal ColA₁ is 1 while the column signal ColBᵢ is 0, and the top plate or top terminal of the resistive memory cell 502a, or V_{reg,1} may be regulated to (Vₒₙ+Vᵣₑₛₑₜ). As Vₒₙ is at least substantially stable, even with different currents, when the diode 504a is turned on, the voltage across the resistive memory cell 502a may be regulated or maintained at least substantially approximately Vᵣₑₛₑₜ.

In embodiments where any of the feedback NMOS transistors, e.g. 534a, 534b, 564a, 564b may not be fully turned on, it may be replaced with a PMOS transistor or a pass gate which passes the analog voltage bit line to the non-inverting input (V₊), e.g. 530, 560. As the feedback transistors are used to pass analog levels, if the feedback voltage is high or close to that of the power supply line, V_{DD1}, V_{DD2}, NMOS transistors may be difficult to turn on, and therefore PMOS transistors or pass gates may be used instead.

In various embodiments, each bit line 524a, 524b has two column control signals which may be expressed as

ColAᵢ=Colᵢ*!Data*WE;

ColBᵢ=Colᵢ*Data*WE

where Colᵢ refers to the column selecting address for the i-th column, “Data” refers to the information/data to be written to the resistive memory cell, “WE” refers to the write enable signal, “!” represents an inverse function, “*” represents an AND function, ColAᵢ is the column control signal for the i-th column and associated with the controlled voltage source including the pass transistor 520 and the other corresponding features as described above, and ColBᵢ is the column control signal for the i-th column and associated with the second controlled voltage source including the second pass transistor 550 and the other corresponding features as described above.

In order to write data to a resistive memory cell using the controlled voltage source including the pass transistor 520, ColAᵢ is determined by the combination of Colᵢ and WE and the inverse of Data. That is, ColAᵢ is enabled (e.g. logic ‘1’) only when Colᵢ, WE are enabled (e.g. logic ‘1’) and that Data is low (e.g. logic ‘0’). For all other combinations, ColAᵢ is disabled (e.g. logic ‘0’).

In order to write data to a resistive memory cell using the second controlled voltage source including the second pass transistor 550, ColBᵢ is determined by the combination of Colᵢ and WE and Data. That is, ColBᵢ is enabled (e.g. logic ‘1’) only when Colᵢ and WE are enabled (e.g. having a logic ‘1’) and that Data is high (e.g. logic ‘1’). For all other combinations, ColBᵢ is disabled (e.g. logic ‘0’).

Therefore, in various embodiments, the controlled voltage source is configured to supply a voltage (i.e writing voltage) to the resistive memory cell 502a, 502b for a write operation (SET or RESET), and the second controlled voltage source is configured to supply another voltage (i.e second writing voltage) to the resistive memory cell 502a, 502b for a second write operation (RESET or SET).

As illustrated in FIG. 3A, the RESET writing voltage (e.g. 304) is of a higher amplitude than the SET writing voltage (e.g. 300). After a RESET operation, the writing voltage may be reduced and as the writing voltage falls in between V_{th, set} 302 and V_{th, reset} 306, and as the writing voltage is above the SET threshold voltage, V_{th,set}, 302, the resistive memory cell may be SET.

Therefore, in various embodiments, in order to prevent the resistive memory cells 502a, 502b from being changed to “SET” after the “RESET” operation, the writing circuit 500 may include a plurality of discharge circuits, e.g. 580a, 580b for discharging the respective bit lines 524a, 524b. A respective discharge circuit 580a, 580b is electrically coupled between the respective bit line 524a, 524b and a ground terminal 582a, 582b.

In various embodiments, each discharge circuit 580a, 580b may include or may be a transistor (e.g. an NMOS transistor) controllable or addressable by a respective column signal (ColC₁, ColC₂, . . . , ColCₙ) to discharge the respective bit line 524a, 524b, after the RESET write operation. The respective column signal ColCᵢ may be a function of the respective column signal ColAᵢ for RESET of the respective resistive memory cell 502a, 502b. For example, ColCᵢ is only high, and the respective discharge transistor 580a, 580b enabled, immediately after the negative edge or falling edge of ColAᵢ and becomes low again after a short time period. It should be appreciated that each discharge circuit 580a, 580b may also be configured to discharge the respective bit line 524a, 524b after the SET write operation.

In various embodiments, each discharge circuit 580a, 580b may include or may be a transistor (e.g. an NMOS transistor) controllable or addressable by a respective column signal (ColC₁, ColC₂, . . . , ColCₙ) to discharge the respective bit line 524a, 524b, after the SET write operation, the RESET write operation and a read operation. The respective column signal ColCᵢ may be a combination of a function of the respective column signal ColAᵢ for RESET, and the respective column signal ColBᵢ for SET and the respective read enabled signal, RE, for reading of the respective resistive memory cell 502a, 502b. For example, ColCᵢ is high and the respective discharge transistor 580a, 580b enabled, when the column signal ColAᵢ, the column signal ColBᵢ and the read enable signal RE are low (e.g. ColCᵢ results from an inverse ColAᵢ AND an inverse ColBᵢ AND an inverse RE; ColCᵢ=!ColAᵢ*!ColBᵢ*!RE, where “!” represents an inverse function and “*” represents an AND function).

In various embodiments, each discharge circuit 580a, 580b may include three transistors (e.g. three NMOS transistors) coupled in series to each other, wherein the three transistors are cooperatively controllable to discharge the bit line after the RESET write operation, after the SET write operation and after a read operation. In other words, the three series transistors may allow the respective bit line 524a, 524b to be discharged after the SET write operation, the RESET write operation and the read operation. This may ensure that no RESET write operation and/or SET write operation and/or read operation is performed during discharging or that discharging operation is not enabled during RESET write operation and/or SET write operation and/or read operation.

For example, the first transistor may be controllable by the respective column signal ColAᵢ for RESET, the second transistor may be controllable by the respective column signal ColBᵢ for SET, while the third transistor may be controllable by a respective read enable signal (e.g. RE). Therefore, the bit line may be discharged when all of the three series transistors are enabled, when the column signal ColAᵢ, and the column signal ColBᵢ and the read enable signal RE are low (e.g. !ColAᵢ*!ColBᵢ*!RE, where “!” represents an inverse function and “*” represents an AND function).

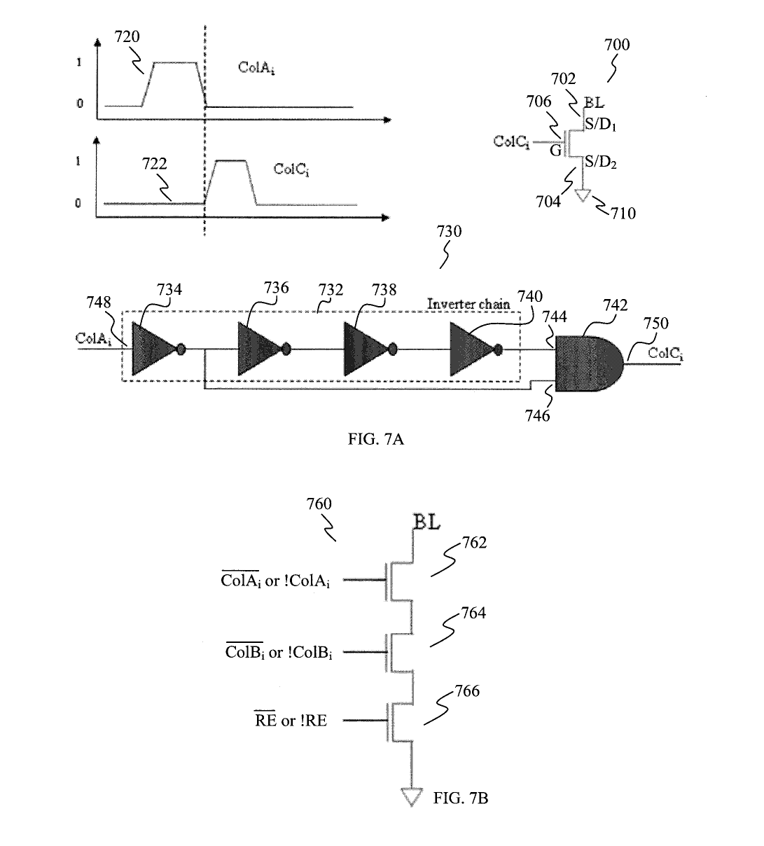

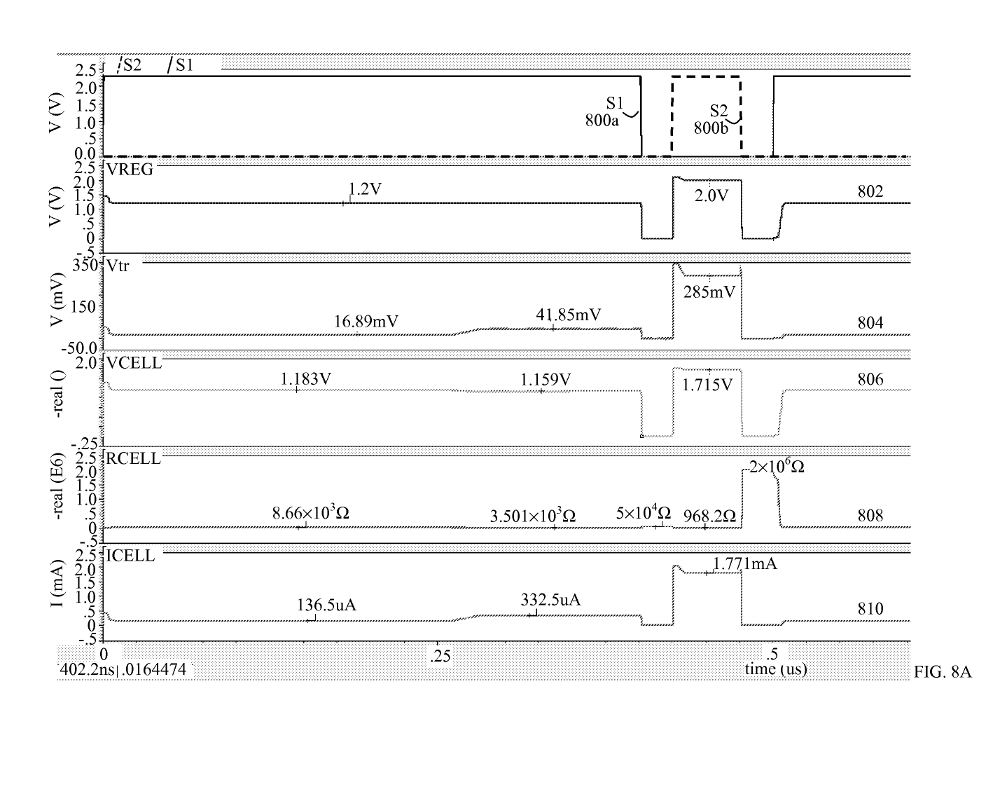

The respective discharge circuit 580a, 580b may be similar to the embodiments as described in the context of FIGS. 7A and 7B.

In various embodiments, the respective diodes 504a, 504b may be replaced with a respective transistor, thereby providing a resistive memory cell arrangement having a 1T1R architecture.

In various embodiments, it should be appreciated that the feedback circuit and/or the second feedback circuit may be a voltage divider as described in the context of the embodiments of FIG. 4.

In various embodiments, it should be appreciated that the writing circuit 500 may include a single controlled voltage source, for example either the controlled voltage source including the pass transistor 520, the plurality of column selecting switches 522a, 522b, the opamp 526 and the feedback circuit including the plurality of feedback transistors 534a, 534b, or the second controlled voltage source including the second pass transistor 550, the plurality of second column selecting switches 552a, 552b, the second opamp 556 and the second feedback circuit including the plurality of second feedback transistors 564a, 564b. In such embodiments, the single controlled voltage source may be configured for performing the SET operation and the RESET operation, with either (Vₒₙ+Vₛₑₜ) or (Vₒₙ+Vᵣₑₛₑₜ) provided to the inverting input (V₋) of the opamp at any one time. Therefore, one or more resistive memory cells 502a, 502b may be written to either the logic state ‘1’ (SET operation) or the logic state ‘0’ (RESET operation), sequentially or in parallel, at different times.

While the writing circuit 500 may provide a regulated voltage to each resistive memory cell 502a, 502b, there may be challenges in that the voltage drops on the column selecting switches, e.g. 522a, 522b, 552a, 552b, may affect the power supply voltage and power consumption.

FIG. 6A shows a schematic of a writing circuit 600, according to various embodiments, for a resistive memory cell arrangement. The resistive memory cell arrangement may include a plurality of resistive memory cells (e.g. PCRAM cells), e.g. PCRAM1 602a, PCRAM2 602b, respectively coupled in series to a plurality of diodes, e.g. 604a, 604b in the respective columns, e.g. 606a, 606b. The plurality of diodes, e.g. 604a, 604b are also coupled to a word line 608. As one diode 604a, 604b is associated or coupled with a resistive memory cell 602a, 602b, the resistive memory cell arrangement has a 1D1R architecture. In various embodiments, the word line 608 may be selected when the word line 608 is set to logic ‘0’ (e.g. Rowb=j).

The writing circuit 600 includes a controlled voltage source including a plurality of pass transistors (or biasing transistors), e.g. M₁ 620a, M₂ 620b, and a plurality of switches, e.g. 622a, 622b. Each pass transistor 620a, 620b includes a first source/drain terminal (S/D₁), a second source/drain terminal (S/D₂) and a gate terminal (G). The first source/drain terminal (S/D₁) is electrically coupled to a power supply line, V_{DD}, and the second source/drain terminal (S/D₂) is electrically coupled to a bit line, e.g. 624a, 624b and the resistive memory cell 602a, 602b. In various embodiments, each pass transistor 620a, 620b may be directly connected to the bit line 624a, 624b associated with the resistive memory cell 602a, 602b. Each switch 622a, 622b is configured to control the gate terminal (G) of a pass transistor 620a, 620b.

The controlled voltage source further includes an opamp 626 having an inverting input (V₋) 628, a non-inverting input (V₊) 630 and an output 632. Each switch 622a, 622b may be coupled or electrically coupled to the output 632 of the opamp 626 for controlling the gate terminal (G) of the respective pass transistor 620a, 620b based on an output signal from the output 632.

The controlled voltage source further includes a feedback circuit including a plurality of feedback transistors (e.g. NMOS transistors), e.g. 634a, 634b, electrically coupled to the non-inverting input (V₊) 630 of the opamp 626 and the respective bit lines 624a, 624b associated with the respective resistive memory cells 602a, 602b to feed back the voltage at the respective bit lines 624a, 624b to the non-inverting input (V₊) 630 of the opamp 626.

The first feedback source/drain terminal (S/D₁) of each feedback transistor 634a, 634b is electrically coupled to the bit line 624a, 624b associated with the respective resistive memory cells 602a, 602b and the second feedback source/drain terminal (S/D₂) of each feedback transistor 634a, 634b is electrically coupled to the non-inverting input (V₊) 630 of the opamp 626. Therefore, the second source/drain terminal (S/D₂) of each pass transistor 620a, 620b is also electrically coupled to the first feedback source/drain terminal (S/D₁) of the respective feedback transistor 634a, 634b. The gate terminal (G) of each feedback transistor 634a, 634b may be controllable or addressable by a respective column signal (ColA₁, ColA₂, . . . , ColAₙ). The respective column signal (ColA₁, ColA₂, . . . , ColAₙ) may also be employed to control (e.g. open and close) the respective switches 622a, 622b.

The controlled voltage source further includes a plurality of control transistors (e.g. PMOS transistors), e.g. 636a, 636b, electrically coupled to the power supply line, V_{DD}, and the respective pass transistors 620a, 620b associated with the respective resistive memory cells 602a, 602b. The first control source/drain terminal of each control transistor 636a, 636b is electrically coupled to the gate terminal of the respective pass transistors 620a, 620b and the second control source/drain terminal of each control transistor 636a, 636b is electrically coupled to the power supply line, V_{DD}. The gate terminal (G) of each control transistor 636a, 636b may be controllable or addressable by a respective column signal (ColA₁, ColA₂, . . . , ColAₙ).

The writing circuit 600 including the controlled voltage source may be configured for performing either of the SET operation or the RESET operation, with either (Vₒₙ+Vₛₑₜ) or Vₒₙ+Vᵣₑₛₑₜ provided to the inverting input (V₋) 628 of the opamp 626 at any one time. Therefore, one or more resistive memory cells 602a, 602b may be written to either the logic state ‘1’ (SET operation) or the logic state ‘0’ (RESET operation), sequentially or in parallel, at different times. Therefore, in various embodiments, the controlled voltage source is configured to supply a voltage (i.e. writing voltage) to the resistive memory cells 602a, 602b to perform both the SET write operation and the RESET write operation, but at different times for the respective write operations.

In operation, using the example that the controlled voltage source is configured for the RESET operation, a voltage (Vₒₙ+Vᵣₑₛₑₜ) may be provided to the inverting input (V₋) 628 of the opamp 626, where Vₒₙ is the turn on voltage of the diodes 604a, 604b, and Vᵣₑₛₑₜ is the RESET voltage for the resistive memory cells 602a, 602b. A voltage V_{reg}, may be generated at each bit line 624a, 624b and is fed back via the respective feedback transistors 634a, 634b to the non-inverting input (V₊) 630 of the opamp 626 as V_{in+,1}. The opamp 626 may act as a feedback amplifier to amplify the error voltage between (Vₒₙ+Vᵣₑₛₑₜ) and V_{in+,1} and based on this amplification of the difference between (Vₒₙ+Vᵣₑₛₑₜ) and V_{in+,1}, produces an output signal at the output 632. Using the column 606a as a non-limiting example, when the switch 622a is closed, the switch 622a controls the gate terminal (G) of the pass transistor 620a based on the output signal from the output 632 for regulating the voltage V_{reg,1}. When the fed back voltage, V_{in+,1}, is at least substantially equal to (Vₒₙ+Vᵣₑₛₑₜ), the voltage V_{reg}, may be regulated at (Vₒₙ+Vᵣₑₛₑₜ). Therefore, the voltage, V_{pcram}, across the resistive memory cell 602a may be regulated at Vᵣₑₛₑₜ, as Vₒₙ is at least substantially stable, even with different currents, when the diode 604a is turned on. It should be appreciated that the controlled voltage source may be configured instead for the SET operation, and a voltage (Vₒₙ+Vₛₑₜ) may be provided to the inverting input (V₋) 628 of the opamp 626. The voltage, V_{pcram}/across the resistive memory cell, for example 602a, may then be regulated at Vₛₑₜ.

As a non-limiting example of writing a logic ‘0’ to the resistive memory cell 602a, the column signal ColA₁ is set to ‘1’, and the top plate or top terminal of the resistive memory cell 602a, or V_{reg,1} may be regulated to Vₒₙ+Vᵣₑₛₑₜ. As Vₒₙ is at least substantially stable, even with different currents, when the diode 604a is turned on, the voltage across the resistive memory cell 602a may be regulated or maintain at least substantially approximately Vᵣₑₛₑₜ.

In various embodiments, each bit line 524a, 524b has the column control signal which may be expressed as

ColAᵢ=Colᵢ*!Data*WE;

where Colᵢ refers to the column selecting address for the i-th column, “Data” refers to the information/data to be written to the resistive memory cell, “WE” refers to the write enable signal, “*” represents an AND function, and ColAᵢ is the column control signal for the i-th column and associated with the controlled voltage source as described above.

In order to write data to a resistive memory cell using the controlled voltage source, ColAᵢ is determined by the combination of Colᵢ and WE and the inverse of Data. That is, ColAᵢ is enabled (e.g. logic ‘1’) only when Colᵢ and WE are enabled (e.g. logic ‘1’) and that Data is low (e.g. logic ‘0’). For all other combinations, ColAᵢ is disabled (e.g. logic ‘0’).

As illustrated in FIG. 6A and its corresponding descriptions, the controlled voltage source of FIG. 6A differs from either the controlled voltage source or the second controlled voltage source of FIG. 5 in that a plurality of pass transistors 620a, 620b are provided, with one pass transistor 620a, 620b per one bit line 624a, 624b, and that the plurality of column selecting switches (e.g. 522a, 522b) are removed from the plurality of bit lines (e.g. 524a, 52b) in the respective columns (e.g. 506a, 506b) and replaced by a plurality of switches 622a, 622b corresponding to the plurality of pass transistors 620a, 620b. Therefore, the controlled voltage source in the context of the embodiments of FIG. 6A is free of any switch or column selecting switch along an electrical path defined between the second source/drain terminal (S/D₂) of a pass transistor 620a, 620b and a respective bit line 624a, 624b. In other words, the controlled voltage source in the context of the embodiments of FIG. 6A is free of any switch or column selecting switch in any one of the columns 606a, 606b. Therefore, the voltage drop associated with a column selecting switch (e.g. 522a, 522b) may be avoided in a column (e.g. 606a, 606b). Therefore, a smaller power supply voltage V_{DD} may be provided and a lower power consumption by the writing circuit 600.

Accordingly, writing to a resistive memory cell 602a, 602b may be controlled by the switch 622a, 622b controlling the gate terminal (G) of the pass transistor 620a, 620b, instead of being controlled by the column selecting switch 522a, 522b. In other words, a column (e.g. 606a, 606b) may be controlled by controlling (e.g. turning on/off) the gate terminal (G) of the respective pass transistor 620a, 620b.

In various embodiments, in order to prevent the resistive memory cells 602a, 602b from being changed to “SET” after the “RESET” operation, the writing circuit 600 may include a plurality of discharge circuits, e.g. 680a, 680b for discharging the respective bit lines 624a, 624b. A respective discharge circuit 680a, 680b is electrically coupled between the respective bit line 624a, 624b and a ground terminal 682a, 682b.

In various embodiments, each discharge circuit 680a, 680b may include or may be a transistor (e.g. an NMOS transistor) controllable or addressable by a respective column signal (ColC₁, ColC₂, . . . , ColCₙ) to discharge the respective bit line 624a, 624b, after the RESET write operation. The respective column signal ColCᵢ may be a function of the respective column signal ColAᵢ for RESET of the respective resistive memory cell 602a, 602b. For example, ColCᵢ is only high, and the respective discharge transistor 680a, 680b enabled, immediately after the negative edge or falling edge of ColAᵢ and becomes low again after a short time period. It should be appreciated that each discharge circuit 680a, 680b may also be configured to discharge the respective bit line 624a, 624b after the SET write operation.

In various embodiments, each discharge circuit 680a, 680b may include or may be a transistor (e.g. an NMOS transistor) controllable or addressable by a respective column signal (ColC₁, ColC₂, . . . , ColCₙ) to discharge the respective bit line 624a, 624b, after the SET write operation, the RESET write operation and a read operation. The respective column signal ColCᵢ may be a combination of a function of the respective column signal ColAᵢ for RESET/SET and the respective read enabled signal, RE, for reading of the respective resistive memory cell 602a, 602b. For example, ColCᵢ is high and the respective discharge transistor 680a, 680b enabled, when the column signal ColAᵢ and the read enable signal RE are low (e.g. ColCᵢ results from an inverse ColAᵢ AND an inverse RE; ColCᵢ=!ColAᵢ*!RE, where “!” represents an inverse function and “*” represents an AND function).

In various embodiments, each discharge circuit 680a, 680b may include two transistors (e.g. two NMOS transistors) coupled in series to each other, wherein the two transistors are cooperatively controllable to discharge the bit line after the RESET write operation or the SET write operation, and after a read operation. In other words, the two series transistors may allow the respective bit line 624a, 624b to be discharged after the SET write operation/RESET write operation, and the read operation. This may ensure that no RESET/SET write operation and/or read operation is performed during discharging or that discharging operation is not enabled during RESET/SET write operation and/or read operation.

For example, the first transistor may be controllable by the respective column signal ColAᵢ for RESET/SET, while the second transistor may be controllable by a respective read enable signal (e.g. RE). Therefore, the bit line may be discharged when both of the two series transistors are enabled, when the column signal ColAᵢ, and the read enable signal RE are low (e.g. !ColAᵢ*!RE, where “!” represents an inverse function and “*” represents an AND function).

The respective discharge circuit 680a, 680b may be similar to the embodiments as described in the context of FIGS. 7A and 7B.

In various embodiments, it should be appreciated that the feedback circuit may be a voltage divider as described in the context of the embodiments of FIG. 4.

FIG. 6B shows a schematic of a writing circuit 610, according to various embodiments, for a resistive memory cell arrangement. The resistive memory cell arrangement may be as described in the context of FIG. 6A. The writing circuit 610 includes a controlled voltage source including a plurality of pass transistors 620a, 620b, a plurality of switches 622a, 622b, an opamp 626, a feedback circuit including a plurality of feedback transistors 634a, 634b, and a plurality of control transistors 636a, 636b, as described in the context of FIG. 6A, and therefore the related descriptions are not repeated here.

The writing circuit 610 further includes a second controlled voltage source including a plurality of second switches, e.g. 652a, 652b. Each second switch 652a, 652b is configured to control the gate terminal (G) of the pass transistor 620a, 620b.

The second controlled voltage source further includes a second opamp 656 having an inverting input (V₋) 658, a non-inverting input (V₊) 660 and an output 662. Each second switch 652a, 652b may be coupled or electrically coupled to the output 662 of the second opamp 656 for controlling the gate terminal (G) of the respective pass transistor 620a, 620b based on an output signal from the output 662.

The second controlled voltage source further includes a second feedback circuit including a plurality of second feedback transistors (e.g. NMOS transistors), e.g. 664a, 664b, electrically coupled to the non-inverting input (V₊) 660 of the second opamp 656 and the respective bit lines 624a, 624b associated with the respective resistive memory cells 602a, 602b to feed back the voltage at the respective bit lines 624a, 624b to the non-inverting input (V₊) 660 of the second opamp 656.

The first feedback source/drain terminal (S/D₁) of each second feedback transistor 664a, 664b is electrically coupled to the bit line 624a, 624b associated with the respective resistive memory cells 602a, 602b and the second feedback source/drain terminal (S/D₂) of each second feedback transistor 664a, 664b is electrically coupled to the non-inverting input (V₊) 660 of the opamp 656. Therefore, the second source/drain terminal (S/D₂) of each pass transistor 620a, 620b is also electrically coupled to the first feedback source/drain terminal (S/D₁) of the respective second feedback transistor 664a, 664b. The gate terminal (G) of each second feedback transistor 664a, 664b may be controllable or addressable by a respective column signal (ColB₁, ColB₂, . . . , ColBₙ). The respective column signal (ColB₁, ColB₂, . . . , ColBₙ) may also be employed to control (e.g. open and close) the respective second switches 652a, 652b.

The second controlled voltage source further includes a plurality of second control transistors (e.g. PMOS transistors), e.g. 666a, 666b, where a respective second control transistor 666a, 666b is coupled in series with the respective control transistor 636a, 636b. The first control source/drain terminal of each second control transistor 666a, 666b is electrically coupled to the gate terminal of the respective pass transistors 620a, 620b and the second control source/drain terminal of each second control transistor 666a, 666b is electrically coupled to the power supply line, V_{DD} (or the first control source/drain terminal of the respective control transistor 636a, 636b). The gate terminal (G) of each second control transistor 666a, 666b may be controllable or addressable by a respective column signal (ColB₁, ColB₂, . . . , ColBₙ).

In operation, using the example that the controlled voltage source including the opamp 626 is configured for the RESET operation, a voltage (Vₒₙ+Vᵣₑₛₑₜ) may be provided to the inverting input (V₋) 628 of the opamp 626, where Vᵣₑₛₑₜ is the turn on voltage of the diodes 604a, 604b, and Vᵣₑₛₑₜ is the RESET voltage for the resistive memory cells 602a, 602b. A voltage V_{reg}, may be generated at each bit line 624a, 624b and is fed back via the respective feedback transistors 634a, 634b to the non-inverting input (V₊) 630 of the opamp 626 as V_{in+,1}. The opamp 626 may act as a feedback amplifier to amplify the error voltage between (Vₒₙ+Vᵣₑₛₑₜ) and V_{in+,1} and based on this amplification of the difference between (Vₒₙ+Vᵣₑₛₑₜ) and V_{in+,1}, produces an output signal at the output 632. Using the column 606a as a non-limiting example, when the switch 622a is closed, the switch 622a controls the gate terminal (G) of the pass transistor 620a based on the output signal from the output 632 for regulating the voltage V_{reg,1}. When the fed back voltage, V_{in+,1}, is at least substantially equal to (Vₒₙ+Vᵣₑₛₑₜ), the voltage V_{reg}, may be regulated at (Vₒₙ+Vᵣₑₛₑₜ). Therefore, the voltage, V_{pcram}/across the resistive memory cell 602a may be regulated at Vᵣₑₛₑₜ/as Vₒₙ is at least substantially stable, even with different currents, when the diode 604a is turned on. It should be appreciated that the controlled voltage source may be configured instead for the SET operation.

In operation, using the example that the second controlled voltage source including the second opamp 656 is configured for the SET operation, a voltage (Vₒₙ+Vₛₑₜ) may be provided to the inverting input (V₋) 658 of the second opamp 656, where Vₒₙ is the turn on voltage of the diodes 604a, 604b, and Vₛₑₜ is the SET voltage for the resistive memory cells 602a, 602b. A voltage V_{reg,2} may be generated at each bit line 624a, 624b and is fed back via the respective feedback transistors 664a, 664b to the non-inverting input (V₊) 660 of the opamp 656 as V_{in+,2}. The second opamp 656 may act as a feedback amplifier to amplify the error voltage between (Vₒₙ+Vₛₑₜ) and V_{in+,2} and based on this amplification of the difference between (Vₒₙ+Vₛₑₜ) and V_{in+,2}, produces an output signal at the output 662. Using the column 606b as a non-limiting example, when the second switch 652b is closed, the second switch 652b controls the gate terminal (G) of the pass transistor 620b based on the output signal from the output 662 for regulating the voltage V_{reg,2}. When the fed back voltage, V_{in+,2}, is at least substantially equal to (Vₒₙ+Vₛₑₜ), the voltage V_{reg,2} may be regulated at (Vₒₙ+Vₛₑₜ). Therefore, the voltage, V_{pcram}/across the resistive memory cell 602b may be regulated at Vₛₑₜ, as Vₒₙ is at least substantially stable, even with different currents, when the diode 604b is turned on. It should be appreciated that the second controlled voltage source may be configured instead for the RESET operation.

It should be appreciated that the two controlled voltage sources may have a similar architecture and/or may be operated in a similar fashion for writing to the plurality of resistive memory cells 602a, 602b. Either of the two controlled voltage sources may be configured for either the SET write operation or the RESET write operation, as long as the two controlled voltage sources are configured for different write operations.

By having two controlled voltage sources, respectively including an opamp, a feedback circuit and a plurality of column selecting switches, the plurality of resistive memory cells 602a, 602b may be written in parallel, with one or more resistive memory cells 602a, 602b written to the logic state ‘1’ (SET operation), and one or more resistive memory cells 602a, 602b written to the logic state ‘0’ (RESET operation).

As a non-limiting example of writing a logic ‘0’ to the resistive memory cell 602a, the column signal ColA₁ is ‘1’ while the column signal ColB₁ is ‘0’, the top plate or top terminal of the resistive memory cell 602a, or V_{reg,1} may be regulated to Vₒₙ+Vᵣₑₛₑₜ. As Vₒₙ is at least substantially stable, even with different currents, when the diode 604a is turned on, the voltage across the resistive memory cell 602a may be regulated or maintain at least substantially approximately Vᵣₑₛₑₜ.

In various embodiments, each bit line 624a, 624b has two column control signals which may be expressed as

ColAᵢ=Colᵢ*!Data*WE;

ColBᵢ=Colᵢ*Data*WE

where Colᵢ refers to the column selecting address for the i-th column, “Data” refers to the information/data to be written to the resistive memory cell, “WE” refers to the write enable signal, “!” represents an inverse function, “*” represents an AND function, ColAᵢ is the column control signal for the i-th column and associated with the controlled voltage source including the opamp 626 and the other corresponding features as described above, ColBᵢ is the column control signal for the i-th column and associated with the second controlled voltage source including the second opamp 656 and the other corresponding features as described above.

In order to write data to a resistive memory cell using the controlled voltage source including the opamp 626, ColAᵢ is determined by the combination of Colᵢ and WE and the inverse of Data. That is, ColAᵢ is enabled (e.g. logic ‘1’) only when Colᵢ, WE are enabled (e.g. logic ‘1’) and that Data is low (e.g. logic ‘0’). For all other combinations, ColAᵢ is disabled (e.g. logic ‘0’).

In order to write data to a resistive memory cell using the second controlled voltage source including the second opamp 656, ColBᵢ is determined by the combination of Colᵢ and WE and Data. That is, ColBᵢ is enabled (e.g. logic ‘1’) only when Colᵢ and WE are enabled (e.g. having a logic ‘1’) and that Data is high (e.g. logic ‘1’). For all other combinations, ColBᵢ is disabled (e.g. logic ‘0’).

Therefore, in various embodiments, the controlled voltage source is configured to supply a voltage (i.e writing voltage) to the resistive memory cell 602a, 602b for a write operation (SET or RESET), and the second controlled voltage source is configured to supply another voltage (i.e second writing voltage) to the resistive memory cell 602a, 602b for a second write operation (RESET or SET).

In various embodiments, in order to prevent the resistive memory cells 602a, 602b from being changed to “SET” after the “RESET” operation, the writing circuit 610 may include a plurality of discharge circuits, e.g. 684a, 684b for discharging the respective bit lines 624a, 624b. A respective discharge circuit 684a, 684b is electrically coupled between the respective bit line 624a, 624b and a ground terminal 686a, 686b.

In various embodiments, each discharge circuit 684a, 684b may include or may be a transistor (e.g. an NMOS transistor) controllable or addressable by a respective column signal (ColC₁, ColC₂, . . . , ColCₙ) to discharge the respective bit line 624a, 624b, after the RESET write operation. The respective column signal ColCᵢ may be a function of the respective column signal ColAᵢ for RESET of the respective resistive memory cell 602a, 602b. For example, ColCᵢ is only high, and the respective discharge transistor 684a, 684b enabled, immediately after the negative edge or falling edge of ColAᵢ and becomes low again after a short time period. It should be appreciated that each discharge circuit 684a, 684b may also discharge the respective bit line 624a, 624b after the SET write operation, for example the respective column signal ColCᵢ may be a function of the respective column signal ColBᵢ for SET of the respective resistive memory cell 602a, 602b.

In various embodiments, each discharge circuit 684a, 684b may include or may be a transistor (e.g. an NMOS transistor) controllable or addressable by a respective column signal (ColC₁, ColC₂, . . . , ColCₙ) to discharge the respective bit line 624a, 624b, after the SET write operation, the RESET write operation and a read operation. The respective column signal ColCᵢ may be a combination of a function of the respective column signal ColAᵢ for RESET, and the respective column signal ColBᵢ for SET and the respective read enabled signal, RE, for reading of the respective resistive memory cell 602a, 602b. For example, ColCᵢ is high and the respective discharge transistor 684a, 684b enabled, when the column signal ColAᵢ, the column signal ColBᵢ and the read enable signal RE are low (e.g. ColCᵢ results from an inverse ColAᵢ AND an inverse ColBᵢ AND an inverse RE; ColCᵢ=!ColAᵢ*!ColBᵢ*!RE, where “!” represents an inverse function and “*” represents an AND function).

In various embodiments, each discharge circuit 684a, 684b may include three transistors (e.g. three NMOS transistors) coupled in series to each other, wherein the three transistors are cooperatively controllable to discharge the bit line after the RESET write operation, after the SET write operation and after a read operation. In other words, the three series transistors may allow the respective bit line 624a, 624b to be discharged after the SET write operation and the RESET write operation and the read operation. This may ensure that no RESET write operation and/or SET write operation and/or read operation is performed during discharging or that discharging operation is not enabled during RESET write operation and/or SET write operation and/or read operation.

For example, the first transistor may be controllable by the respective column signal ColAᵢ for RESET, the second transistor may be controllable by the respective column signal ColBᵢ for SET, while the third transistor may be controllable by a respective read enable signal (e.g. RE). Therefore, the bit line may be discharged when all of the three series transistors are enabled, when the column signal ColAᵢ, and the column signal ColBᵢ and the read enable signal RE are low (e.g. !ColAᵢ*!ColBᵢ*!RE, where “!” represents an inverse function and “*” represents an AND function).

The respective discharge circuit 684a, 684b may be similar to the embodiments as described in the context of FIGS. 7A and 7B.

In various embodiments, it should be appreciated that the feedback circuit may be a voltage divider as described in the context of the embodiments of FIG. 4.

FIG. 6C shows a schematic of a simplified representation or equivalent circuit of the writing circuit of the embodiments of FIGS. 6A and 6B, using the controlled voltage source including the opamp 626 and the column 606a as a non-limiting example, during a write operation. As illustrated, the gate terminal (G) of the feedback transistor 634a may be coupled to a power supply line, V_{DD}, and the word line 608 may be set to ground (e.g. logic ‘0’).

FIG. 6D shows a schematic of a writing circuit 670, according to various embodiments, for a resistive memory cell arrangement. The resistive memory cell arrangement may include a plurality of resistive memory cells (e.g. PCRAM cells), e.g. PCRAM1 602a, PCRAM2 602b, respectively coupled in series to a plurality of transistors, e.g. 690a, 690b in the respective columns, e.g. 606a, 606b. Each transistor 690a, 690b includes a first source/drain terminal (S/D₁), a second source/drain terminal (S/D₂) and a gate terminal (G). The first source/drain terminal (S/D₁) is electrically coupled to the respective resistive memory cell 602a, 602b, the second source/drain terminal (S/D₂) is coupled to a ground terminal, e.g. 692a, 692b, and the gate terminal (G) is coupled to a word line 608. As one transistor 690a, 690b is associated or coupled with a resistive memory cell 602a, 602b, the resistive memory cell arrangement has a 1T1R architecture. In various embodiments, the word line 608 may be selected when the word line is set to logic ‘1’ (e.g. Row=1).

The writing circuit 670 illustrated in FIG. 6D is similar to the writing circuit 610 as described in the context of FIG. 6B and the descriptions thereof are therefore not repeated here. Furthermore, it should be appreciated that the writing circuit 670 may instead be the writing circuit 600 including a single opamp, as described in the context of FIG. 6A.

FIG. 6E shows a schematic of a simplified representation or equivalent circuit of the writing circuit of the embodiment of FIG. 6D, using the controlled voltage source including the opamp 626 and the column 606a as a non-limiting example, during a write operation. As illustrated, the gate terminal (G) of the feedback transistor 634a may be coupled to a power supply line, V_{DD}, and the word line 608 may be coupled to a power supply line, V_{DD} (e.g. logic ‘1’).

FIG. 7A shows a schematic of a discharge circuit 700, according to various embodiments, for discharging a bit line associated with a resistive memory cell. The discharge circuit 700 may be an NMOS transistor, with its first source/drain terminal (S/D₁) 702 coupled to a bit line (BL), a second source/drain terminal (S/D₂) 704 coupled to a ground terminal 710, and a gate terminal (G) 706 controllable or addressable by a column signal, e.g. ColCᵢ.

In one embodiment, ColCᵢ is only “high” immediately after the negative edge or falling edge of ColAᵢ associated with a write operation, e.g. RESET, and be “low” again after a small period of time, as illustrated by the timing diagram 720 for ColAᵢ and the timing diagram 722 for ColCᵢ as shown in FIG. 7A. The small period of time discharges the bit line immediately through the NMOS transistor 700. FIG. 7A also shows an example of implementation using an arrangement 730 of logic gates for generating ColCᵢ. The arrangement 730 includes an inverter chain 732 having four NOT gates 734, 736, 738, 740 coupled in series. The arrangement 730 further includes an AND gate 742 having one input 744 coupled to the output of the NOT gate 740, and another input coupled to the output of the NOT gate 734. The input 748 of the NOT gate 734 receives the column signal ColAᵢ and the output 750 of the AND gate 742 outputs the column signal ColCᵢ based on an AND operation of the signals received at the two inputs 744, 746. It should be appreciated that any number of NOT gates may be provided in the inverter chain 732, depending on the desired delay time between the leading edge of ColAᵢ and the leading edge of ColCᵢ.

In another embodiment, the NMOS transistor 700 may be controllable by ColCᵢ, where ColCᵢ=!ColAᵢ*!ColBᵢ*!RE, with ColAᵢ being associated with a write operation, e.g. RESET, ColBᵢ being associated with another write operation, e.g. SET, RE being the read enable signal, “!” representing an inverse function and “*” representing an AND function.

FIG. 7B shows a schematic of a discharge circuit 760, according to various embodiments, for discharging a bit line associated with a resistive memory cell. The discharge circuit 760 includes three NMOS transistors 762, 764, 766, coupled in series to each other. The three NMOS transistors 762, 764, 766 may be controllable by !ColAᵢ, !ColBᵢ and !RE respectively. As a non-limiting example, the NMOS transistor 762 may be controllable by !ColAᵢ, the NMOS transistor 764 may be controllable by !ColBᵢ and the NMOS transistor 766 may be controllable by !RE, for example where ColAᵢ is associated with a write operation, e.g. RESET, ColBᵢ is associated with another write operation, e.g. SET, and RE is the read enable signal. Therefore, the bit line may be discharged after the write operation, the other write operation and the read operation.

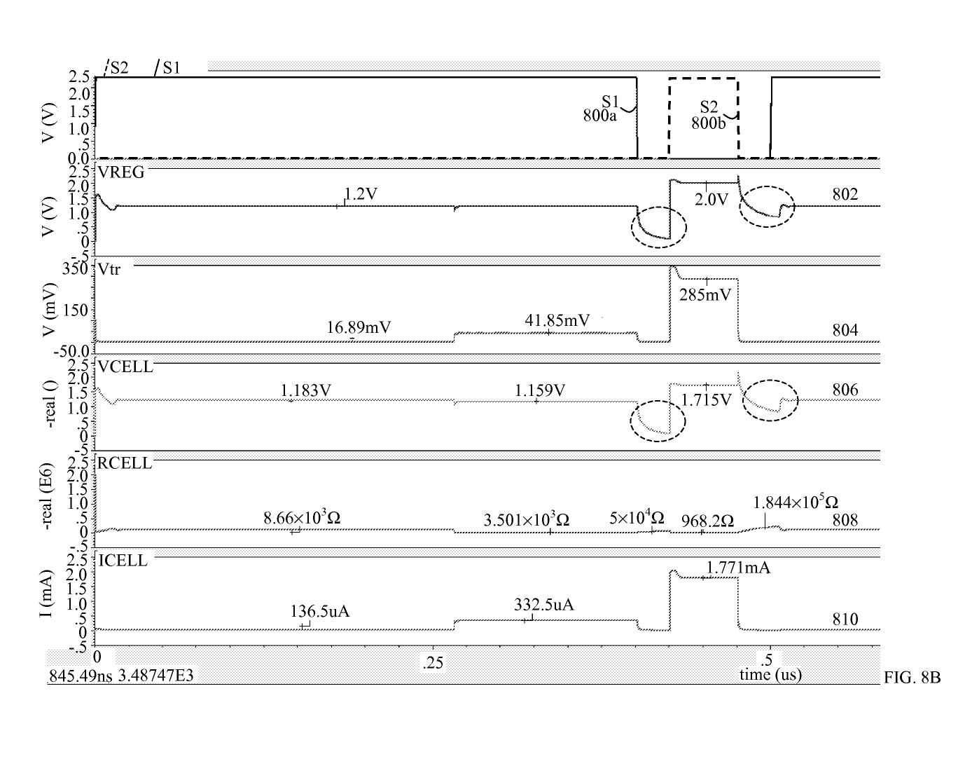

FIG. 8A shows simulation results of waveforms for a writing circuit of various embodiments with discharge circuits, based on the embodiment of FIG. 6D. A write ‘1’ pulse, S1 800a, may be imposed on a resistive memory cell (e.g. a PCRAM cell) (e.g. 602a, 602b) for a SET operation, and after a short period of turned off time, another write ‘0’ pulse, S2 800b, may be imposed on the same resistive memory cell for a RESET operation.

As shown by the voltage V_{reg} waveform 802, V_{reg} may be regulated at about 1.2 V during SET and about 2 V during RESET. The voltage over or across the resistive memory cell, V_{AB} or V_{CELL}, (waveform 806) may change by about 24 mV (=1.183 V−1.159 V) because the voltage over the word line selecting transistor (e.g. 690a, 690b) (waveform 804, Vₜᵣ) may change. However, this voltage change over the word line selecting transistor (waveform 804, Vₜᵣ) may be omitted because the margin or change is much larger than 24 mV.

It should be appreciated that a noise margin may be provided for the write operation. As a non-limiting example, the required SET voltage range may be between about 1 V-1.5 V.

Where the SET voltage is set to about 1.2 V, there will be approximately 0.2 V margin to avoid the resistance distribution and the write voltage distribution, for example, to avoid mis-writing. Therefore, even when the states of the PCRAM cell changes, between amorphous and crystalline, the resistance change is larger than the resistance distribution, such that the SET voltage may remain at least substantially the same. In a multi-level design, the range may be even smaller, therefore, the SET/RESET voltage has to be carefully set to avoid mis-writing.

The waveform 808 (R_{CELL}) shows the resistance of the resistive memory cell while the waveform 810 (I_{CELL}) shows the writing current flowing through the resistive memory cell.

From the simulation waveforms of FIG. 8A, it can be observed that although the resistance (waveform 808) of the resistive memory cell or the writing current (waveform 810) changes a lot, the voltage (waveform 806) over or across the resistive memory cell is at least substantially maintained at nearly the same value or voltage.

From simulation, conventional writing circuits require a 3.8 V power supply voltage, compared to about 2.5 V power supply voltage for the writing circuits of various embodiments. Therefore, with the lower power supply voltage, a power of about 2.35 mW (=1.3 V×1.771 mA (waveform 810)) may be saved for each resistive memory cell during RESET.

FIG. 8B shows simulation results of waveforms for a writing circuit of various embodiments without discharge circuits, based on the embodiment of FIG. 6D. As shown in FIG. 8B illustrated by the dashed circles for example for the waveforms 802, 806, the discharge speed of the writing circuit without discharge circuits is slower than the discharge speed of the writing circuit with discharge circuits (results of FIG. 8A).

While the preferred embodiments of the devices and methods have been described in reference to the environment in which they were developed, they are merely illustrative of the principles of the inventions. The elements of the various embodiments may be incorporated into each of the other species to obtain the benefits of those elements in combination with such other species, and the various beneficial features may be employed in embodiments alone or in combination with each other. Other embodiments and configurations may be devised without departing from the spirit of the inventions and the scope of the appended claims.

We claim:

1. A writing circuit for a resistive memory cell arrangement, the resistive memory cell arrangement comprising a plurality of resistive memory cells, the writing circuit comprising:
a controlled voltage source comprising:
a plurality of pass transistors, wherein each pass transistor comprises a first source/drain terminal, a second source/drain terminal and a gate terminal, and wherein the first source/drain terminal is configured to be electrically coupled to a power supply line and the second source/drain terminal is configured to be electrically coupled to a bit line associated with a resistive memory cell of the plurality of resistive memory cells; and
a plurality of switches, wherein each switch is configured to control the gate terminal of the pass transistor,
wherein the controlled voltage source is configured to supply a voltage to the resistive memory cell for a write operation.

2. The writing circuit as claimed in claim 1, wherein the controlled voltage source further comprises an opamp for regulating the voltage during the write operation.

3. The writing circuit as claimed in claim 2, wherein the controlled voltage source further comprises a feedback circuit configured to be electrically coupled to an input of the opamp and the plurality of resistive memory cells.

4. The writing circuit as claimed in claim 3, wherein the feedback circuit comprises a voltage divider.

5. The writing circuit as claimed in claim 3, wherein the feedback circuit comprises:
a plurality of feedback transistors,
wherein each feedback transistor comprises a first feedback source/drain terminal, a second feedback source/drain terminal and a feedback gate terminal, and
wherein the first feedback source/drain terminal is configured to be electrically coupled to the bit line associated with the resistive memory cell and the second feedback source/drain terminal is configured to be electrically coupled to the input of the opamp.

6. The writing circuit as claimed in claim 1, wherein each pass transistor is configured to be directly connected to the bit line associated with the resistive memory cell.

7. The writing circuit as claimed in claim 1, wherein each switch of the plurality of switches is electrically coupled to an output of the opamp for controlling the gate terminal of the pass transistor based on a signal from the output of the opamp.

8. The writing circuit as claimed in claim 1, wherein the controlled voltage source further comprises a plurality of control transistors, wherein each control transistor is configured to be electrically coupled between the gate terminal of the pass transistor and the power supply line.

9. The writing circuit as claimed in claim 3, wherein the opamp has an inverting input and a non-inverting input, and wherein the input is the non-inverting input.

10. The writing circuit as claimed in claim 1, further comprising a plurality of discharge circuits, wherein each discharge circuit of the plurality of discharge circuits is configured to be electrically coupled between the bit line associated with the resistive memory cell and a ground terminal.

11. The writing circuit as claimed in claim 10, wherein each discharge circuit comprises a transistor controllable to discharge the bit line after the write operation.

12. The writing circuit as claimed in claim 10, wherein each discharge circuit comprises a transistor controllable to discharge the bit line after the write operation and a read operation.

13. The writing circuit as claimed in claim 10, wherein each discharge circuit comprises two transistors coupled in series to each other, wherein the two transistors are cooperatively controllable to discharge the bit line after the write operation and after a read operation.

14. The writing circuit as claimed in claim 1, wherein the controlled voltage source is free of any switch along an electrical path defined between the second source/drain terminal and the bit line.

15. The writing circuit as claimed in claim 1, further comprising:
a second controlled voltage source comprising:
a plurality of second switches, wherein each second switch is configured to control the gate terminal of the pass transistor,
wherein the second controlled voltage source is configured to supply a second voltage to the resistive memory cell for a second write operation.

16. The writing circuit as claimed in claim 2, further comprising:
a second controlled voltage source comprising:
a plurality of second switches, wherein each second switch is configured to control the gate terminal of the pass transistor,
wherein the second controlled voltage source is configured to supply a second voltage to the resistive memory cell for a second write operation; and
a second opamp for regulating the second voltage during the second write operation.

17. The writing circuit as claimed in claim 3, further comprising:
a second controlled voltage source comprising:
a plurality of second switches, wherein each second switch is configured to control the gate terminal of the pass transistor,
wherein the second controlled voltage source is configured to supply a second voltage to the resistive memory cell for a second write operation;
a second opamp for regulating the second voltage during the second write operation; and
a second feedback circuit configured to be electrically coupled to an input of the second opamp and the plurality of resistive memory cells.

18. A memory cell arrangement, comprising:
a plurality of resistive memory cells; and
a writing circuit for the plurality of resistive memory cells, the writing circuit comprising:
a controlled voltage source comprising:
a plurality of pass transistors, wherein each pass transistor comprises a first source/drain terminal, a second source/drain terminal and a gate terminal, and wherein the first source/drain terminal is configured to be electrically coupled to a power supply line and the second source/drain terminal is configured to be electrically coupled to a bit line associated with a resistive memory cell of the plurality of resistive memory cells; and
a plurality of switches, wherein each switch is configured to control the gate terminal of the pass transistor,
wherein the controlled voltage source is configured to supply a voltage to the resistive memory cell for a write operation.

19. The memory cell arrangement as claimed in claim 18, wherein the controlled voltage source further comprises an opamp for regulating the voltage during the write operation.

20. The memory cell arrangement as claimed in claim 19, wherein the controlled voltage source further comprises a feedback circuit configured to be electrically coupled to an input of the opamp and the plurality of resistive memory cells.
